(19) United States
(12) Patent Application Publication
(10) Pub. No.: US 2025/0301617 A1
(43) Pub. Date: Sep. 25, 2025

(54) SRAM CELL, METHOD OF MANUFACTURING SRAM CELL, MEMORY INCLUDING SRAM CELL AND ELECTRONIC DEVICE

(71) Applicants: Beijing Superstring Academy of Memory Technology, Beijing (CN); INSTITUTE OF MICROELECTRONICS, CHINESE ACADEMY OF SCIENCES, Beijing (CN)

(72) Inventors: Yongkui ZHANG, Beijing (CN); Wenliang LIU, Beijing (CN); Yong DU, Beijing (CN); Xiaolei WANG, Beijing (CN); Jun LUO, Beijing (CN)

(21) Appl. No.: 19/084,017

(22) Filed: Mar. 19, 2025

(30) Foreign Application Priority Data
Mar. 25, 2024 (CN) 202410345809.1

(51) Int. Cl. H10B 10/00

(52) U.S. Cl. CPC H10B 10/12

(57) ABSTRACT

A Static Random Access Memory (SRAM) cell, a method of manufacturing an SRAM cell, a memory including such SRAM cell and an electronic device are provided. The SRAM cell includes: a substrate; first and second pull-up transistors, first and second pass-gate transistors at substantially a same height relative to the substrate; and first and second pull-down transistors at substantially a same height relative to the substrate, where the first pull-down transistor is stacked on the first pull-up transistor, and the second pull-down transistor is stacked on the second pull-up transistor, where an active region of each of the first and second pull-up transistors, the first and second pull-down transistors, the first and second pass-gate transistors includes a first source/drain layer, a channel layer and a second source/drain layer sequentially disposed in a vertical direction, and the channel layer is in a form of a vertical nanosheet.

### CROSS REFERENCE TO RELATED APPLICATION

This application claims priority to Chinese Patent Application No. 202410345809.1, filed on Mar. 25, 2024, the entire content of which is incorporated herein in its entirety by reference.

### TECHNICAL FIELD

The present disclosure relates to a field of semiconductors, and in particular to a Static Random Access Memory (SRAM) cell, a method of manufacturing an SRAM cell, a memory including such SRAM cell and an electronic device.

### BACKGROUND

In a horizontal device such as a Metal Oxide Semiconductor Field Effect Transistor (MOSFET), a source, a gate and a drain are arranged in a direction substantially parallel to a surface of a substrate. Due to such arrangement, it is difficult to further shrink the horizontal device. In contrast, in a vertical device, a source, a gate and a drain are arranged in a direction substantially perpendicular to a surface of a substrate. Therefore, compared to the horizontal device, it is easier to shrink the vertical device.

In addition, it is desired to improve integration for increasing storage density, thus the vertical device is promising in application to a memory device such as a Static Random Access Memory (SRAM).

### SUMMARY

According to an aspect of the present disclosure, there is provided an SRAM cell, including: a substrate; a first pull-up transistor, a second pull-up transistor, a first pass-gate transistor, and a second pass-gate transistor at substantially a same height relative to the substrate; and a first pull-down transistor and a second pull-down transistor at substantially a same height relative to the substrate, where the first pull-down transistor is stacked on the first pull-up transistor, and the second pull-down transistor is stacked on the second pull-up transistor, and where an active region of each of the first pull-up transistor, the second pull-up transistor, the first pull-down transistor, the second pull-down transistor, the first pass-gate transistor, and the second pass-gate transistor includes a first source/drain layer, a channel layer and a second source/drain layer sequentially disposed in a vertical direction, and the channel layer is in a form of a vertical nanosheet.

According to another aspect of the present disclosure, there is provided a method of manufacturing an SRAM cell, including: sequentially providing a stack of a first group and a second group on a substrate, where the first group includes a first source/drain layer, a first channel defining layer and a second source/drain layer, and the second group includes a first source/drain layer, a second channel defining layer and a second source/drain layer; forming an isolation trench in the stack, such that the stack includes a first region, a second region and a third region, where the second region and the third region are respectively provided on opposite sides of the first region in a first direction and isolated from the first region, the second region includes a first sub-region and a second sub-region opposite to the first sub-region in a second direction, where the first sub-region is electrically isolated from the second sub-region, the third region includes a third sub-region and a fourth sub-region opposite to the third sub-region in the second direction, where the third sub-region is electrically isolated from the fourth sub-region, where the first sub-region and the fourth sub-region are diagonally disposed; forming a hard mask layer on the stack, where the hard mask layer has a rectangular ring pattern, the rectangular ring pattern has edges extending in the first direction and the second direction respectively, and four corners of the rectangular ring pattern are in the first sub-region, the second sub-region, the third sub-region, and the fourth sub-region respectively; patterning an outer side of the stack using the hard mask layer; selectively etching the channel defining layer, such that the channel defining layer is relatively recessed in a lateral direction; forming a channel layer on a vertical sidewall of the channel defining layer; patterning an inner side of the stack using the hard mask layer; removing the first channel defining layer and the second channel defining layer from the inner side of the stack; lowering a height of the stack in the first sub-region to the fourth sub-region and a partial region of the first region to a level between a bottom surface of the second source/drain layer of the first group and a top surface of the first source/drain layer of the second group, where in the partial region of the first region corresponding to a partial length of each of two opposite edges of the rectangular ring pattern extending in the first direction, the stack retains the second group including the first source/drain layer, the second channel defining layer and the second source/drain layer; and forming a gate stack in a space left between the first source/drain layer and the second source/drain layer due to a removal of corresponding channel defining layers in the first channel defining layer and the second channel defining layer.

According to another aspect of the present disclosure, there is provided a memory, including an array of SRAM cells described above.

According to another aspect of the present disclosure, there is provided an electronic device, including the memory device described above.

### BRIEF DESCRIPTION OF THE DRAWINGS

The above and other purposes, features, and advantages of the present disclosure will be clearer through the following description of embodiments of the present disclosure with reference to the accompanying drawings, in which:

FIG. 1 schematically shows an equivalent circuit diagram of a Static Random Access Memory (SRAM) cell;

FIG. 2 schematically shows a perspective view of an SRAM cell according to an embodiment of the present disclosure;

FIG. 3(a) schematically shows a configuration example of an active region of each transistor in the SRAM cell shown in FIG. 2;

FIG. 3(b) schematically shows an example of forming a gate stack on the active region shown in FIG. 3a);

FIG. 3(c) schematically shows a top view of an SRAM cell according to an embodiment of the present disclosure;

FIG. 4(a) to FIG. 35(c) schematically show some stages in a process of manufacturing an SRAM cell according to an embodiment of the present disclosure; and

FIG. 36 schematically shows a layout of an SRAM cell array according to an embodiment of the present disclosure.

Throughout the accompanying drawings, the same or similar reference numerals indicate the same or similar components.

### DETAILED DESCRIPTION OF EMBODIMENTS

Hereinafter, embodiments of the present disclosure will be described with reference to the accompanying drawings. However, it should be understood that these descriptions are only exemplary and are not intended to limit the scope of the present disclosure. In addition, in the following illustration, descriptions of well-known structures and technologies are omitted to avoid unnecessarily confusing the concepts of the present disclosure.

Various structural schematic diagrams according to embodiments of the present disclosure are shown in the drawings. These drawings are not drawn to scale, in which some details are enlarged and some details may be omitted for the purpose of clear expression. Shapes, relative sizes and positional relationships of various regions and layers shown in the drawings are only exemplary, and may be deviated due to manufacturing tolerances or technical limitations in practice. Moreover, those skilled in the art may additionally design regions/layers with different shapes, sizes and relative positions as desired in practice.

In the context of the present disclosure, when a layer/element is described to be “on” another layer/element, the layer/element may be directly on the another layer/element, or there may be an intermediate layer/element therebetween. In addition, if a layer/element is “on” another layer/element in one orientation, the layer/element may be “below” the another layer/element when the orientation is reversed.

According to embodiments of the present disclosure, there is provided a Static Random Access Memory (SRAM) cell based on a vertical nanosheet metal oxide semiconductor field effect transistor (MOSFET). In the SRAM cell, vertical devices used as constituent elements of the SRAM cell may be stacked in a vertical direction, so as to further improve integration.

The present disclosure provides a Static Random Access Memory (SRAM) cell with improved performance, a method of manufacturing an SRAM cell, a memory including such SRAM cell and an electronic device.

According to embodiments of the present disclosure, constituent transistors of the SRAM cell may be arranged in a vertically stacked manner, thereby saving area. The transistors of upper and lower layers may be stacked in a self-aligned manner, thereby further saving area. The channel layer of the transistor may be formed through a separate epitaxial process, so that a material quality of a grown film may be guaranteed and a film thickness may be precisely controlled. In addition, a channel width of the transistor in the SRAM cell may be flexibly set through a photolithography process, so that the entire SRAM cell may flexibly adjust a transistor driving force for each transistor type.

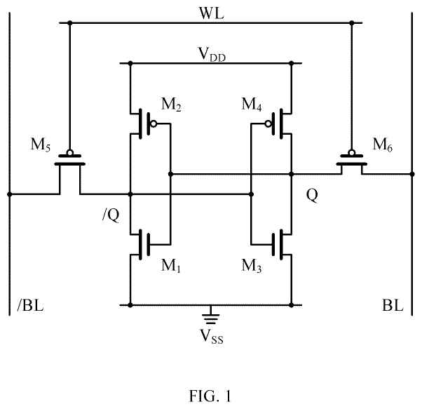

FIG. 1 schematically shows an equivalent circuit diagram of an SRAM cell.

As shown in FIG. 1, the SRAM cell may have 6T structure, that is, including six transistors M₁ to M₆, such as a Field Effect Transistor (FET). Among these six transistors, the four transistors M₁, M₂, M₃, and M₄ may form two cross-coupled inverters as a storage position for storing a bit in the SRAM cell. Another two transistors M₅ and M₆ may control the data transmission between the storage position and a bit line BL and between the storage position and a complementary bit line/BL respectively, under a control of a word line WL, so as to realize reading and writing.

Among the four transistors M₁, M₂, M₃, and M₄ that form the cross-coupled inverters, two p-type transistors M₂ and M₄ may be connected to a power supply voltage V_{DD} and thus may be referred to as “pull-up transistors” (PU), and two n-type transistors M₁ and M₃ may be connected to a ground voltage V_{SS} and thus may be referred to as “pull-down transistors” (PD). The transistors M₅ and M₆ (shown as p-type in FIG. 1, but may also be n-type) may control reading and writing or data transmission, and thus may be referred to as “access control transistors” or “pass-gate transistors” (PG).

Hereinafter, reading and writing operations of such 6T SRAM cell will be briefly described.

First, the reading operation is described. Assuming that the bit stored in the storage position is “1”, that is, it is a high level at a node Q and a low level at a node/Q. At the beginning of a reading cycle, the bit line BL and the complementary bit line/BL may be pre-charged to logic 1, and then the word line WL may be applied with a level that enables the access control transistors M₅ and M₆ to be turned on. Due to the high level at the node Q, the pull-up transistor M₂ is turned off and the pull-down transistor M₁ is turned on. Therefore, the pull-down transistor M₁ and the access control transistor M₅ connect the complementary bit line/BL to ground, thus the pre-charged value on the complementary bit line/BL is discharged, so that the value of 0 is on the complementary bit line/BL. On the other hand, due to the low level at the node/Q, the pull-up transistor M₄ is turned on and the pull-down transistor M₃ is turned off. Therefore, the pull-up transistor M₄ and the access control transistor M₆ connect the bit line BL to the power supply voltage V_{DD}, and thus the pre-charged value is maintained, that is, the value of 1 is on the bit line BL. If the stored bit is “0”, the opposite circuit state will result in a value of 1 on the complementary bit line/BL and a value of 0 on the bit line BL. By distinguishing which of the bit line BL and the complementary bit line/BL has a higher potential, the stored bit “0” or “1” may be read out.

In the writing operation, at the beginning of a writing cycle, a state to be written is loaded to the bit line BL. For example, if “0” is to be written, the bit line BL is set to “0” (and the complementary bit line/BL is set to “1”). Then, the word line WL may be applied with a level that enables the access control transistors M₅ and M₆ to be turned on, and thus the state of the bit line BL is loaded into the storage position of the SRAM cell. This is achieved by designing (the transistor of) the bit line input driver to be stronger than (the transistor of) the storage position so that the bit line state may override the previous state of the cross-coupled inverter in the storage position.

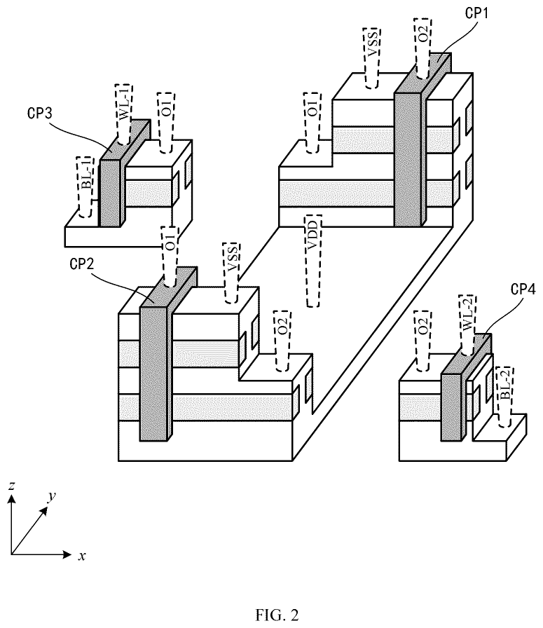

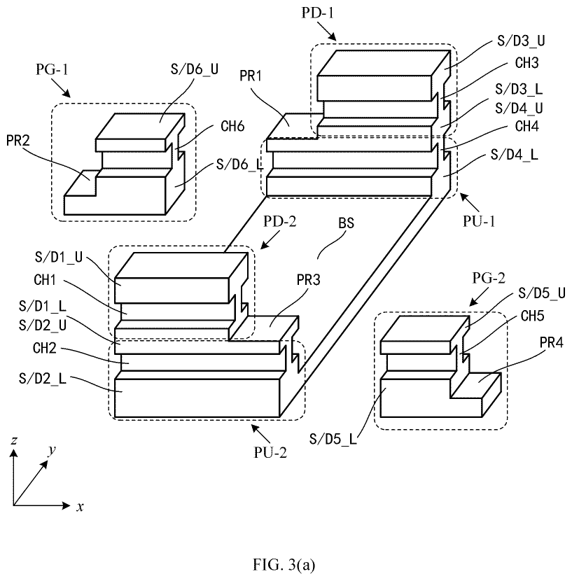

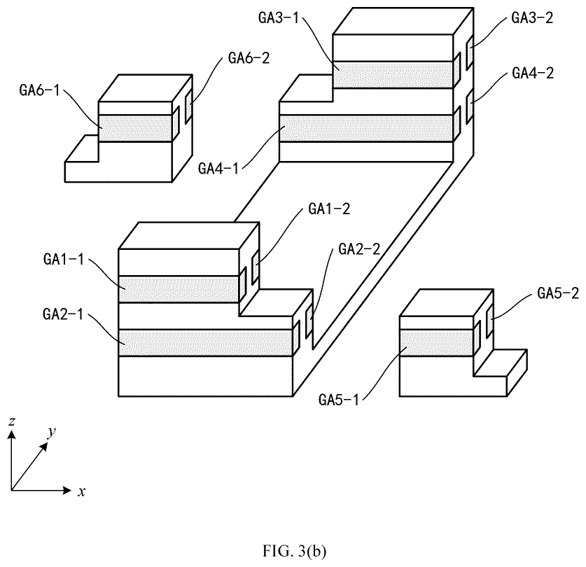

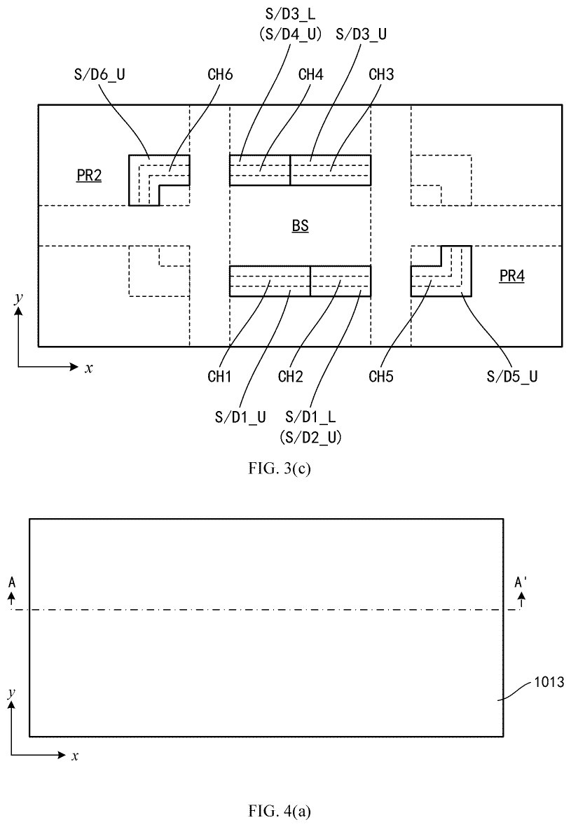

FIG. 2 schematically shows a perspective view of an SRAM cell according to an embodiment of the present disclosure. FIG. 3(a) schematically shows a configuration example of an active region of each transistor in the SRAM cell shown in FIG. 2. FIG. 3(b) schematically shows an example of forming a gate stack on the active region shown in FIG. 3(a).

As shown in FIG. 2, FIG. 3(a), and FIG. 3(b), in the 6T SRAM cell, six transistors may be included, in particular, two pull-up transistors PU-1 and PU-2, two pull-down transistors PD-1 and PD-2, and two pass-gate transistors PG-1 and PG-2. These transistors may be vertical nanosheet transistors.

Each transistor may include an active region extending in a vertical direction (e.g., a direction substantially perpendicular to an upper surface of a substrate) relative to the upper surface of the substrate. The active region may include a channel region and source/drain regions located on two opposite sides of the channel region in the vertical direction. As described below, the active region of the transistor may include a first source/drain layer, a channel layer, and a second source/drain layer sequentially stacked in the vertical direction. The source/drain regions may be substantially formed in the first source/drain layer and the second source/drain layer respectively, and the channel region may be substantially formed in the channel layer. For example, the source/drain regions may be achieved through doping regions in the source/drain layer. The gate stack may surround at least part of a periphery of the channel region.

As shown in the figures, the active region, particularly the channel layer, may have a form of a nanosheet. The nanosheet may have a width in a first direction (e.g., x-direction) and a thickness in a second direction (e.g., y-direction) intersecting with (e.g., perpendicular to) the first direction, and may have a certain height in a vertical direction (e.g., z-direction). Generally, the width of the nanosheet is greater than the thickness of the nanosheet. When the width is small, the nanosheet may be a nanowire. As described below, the widths of respective nanosheets of different devices may be adjusted separately. The first source/drain layer and the second source/drain layer may be substantially self-aligned with the channel layer in the vertical direction.

Unlike the conventional art in which the constituent transistors in the SRAM cell are arranged in a planar layout, according to embodiments of the present disclosure, the constituent transistors in the SRAM cell may be stacked in the vertical direction, so as to further save the area occupied by the SRAM cell. For example, several transistors may be provided on one layer (e.g., at substantially the same first height from the upper surface of the substrate), and the remaining transistors may be provided on another layer (e.g., at substantially the same second height from the upper surface of the substrate, the first height being different from the second height), and the two layers may at least partially overlap in the vertical direction.

In the examples shown in FIG. 2, FIG. 3(a), and FIG. 3(b), the pull-up transistors PU-1 and PU-2, and the pass-gate transistors PG-1 and PG-2 (which may be p-type transistors, or the pull-up transistors PU-1 and PU-2 may be p-type transistors and the pass-gate transistors PG-1 and PG-2 may be n-type transistors) may be provided in a first layer, and the pull-down transistors PD-1 and PD-2 (which may be n-type transistors) may be provided in a second layer. In this example, the second layer is provided on the first layer, but the present disclosure is not limited to this. For example, by flipping the structures shown in FIG. 2, FIG. 3(a), and FIG. 3(b) up and down (with the substrate still left at the bottom) and adjusting the interconnection structures accordingly, the first layer may be provided on the second layer.

According to embodiments of the present disclosure, the pull-down transistor PD-1 may be stacked on the corresponding pull-up transistor PU-1 and may be self-aligned with the corresponding pull-up transistor PU-1, and the pull-up transistor PD-2 may be stacked on the corresponding pull-up transistor PU-2 and may be self-aligned with the corresponding pull-up transistor PU-2. In the drawings and the following description, taking the second layer provided on the first layer as an example, the first layer may be referred to as a lower layer and the second layer may be referred to as an upper layer.

These transistors may be electrically connected to each other according to the 6T layout described above.

As shown in FIG. 2, FIG. 3(a), and FIG. 3(b), a source/drain layer S/D4_U (e.g., in which a drain region is formed) on an upper side of the first pull-up transistor PU-1 may be electrically connected to a source/drain layer S/D3_L (e.g., in which a drain region is formed) on a lower side of the first pull-down transistor PD-1, and a first node therebetween corresponds to, for example, the node Q in FIG. 1. A source/drain layer S/D6_U on an upper side of the first pass-gate transistor PG-1 may be electrically connected to the first node (for example, through a contact portion O1 schematically shown in FIG. 2, each contact portion O1 may be interconnected with each other through an interconnection line in a metal interconnection layer), and a source/drain layer S/D6_L on a lower side of the first pass-gate transistor PG-1 may be electrically connected to a first bit line (for example, the bit line BL in FIG. 1) through a corresponding contact portion BL-1. The source/drain layer S/D4_U on the upper side of the first pull-up transistor PU-1 and the source/drain layer S/D3_L on the lower side of the first pull-down transistor PD-1 may be in direct contact with or integrated with each other. The integrated source/drain layer may have a protruding portion PRI protruding relative to the active region above, so that the corresponding contact portion O1 may be connected thereto. Similarly, the source/drain layer S/D6_L on the lower side of the first pass-gate transistor PG-1 may have a protruding portion PR2 protruding relative to the active region above, so that the contact portion BL-1 may be connected thereto.

Note that the contact portion shown in FIG. 2 is only for illustrating a connection relationship between components and does not represent an actual size of the contact portion (especially a size in the vertical direction).

Similarly, a source/drain layer S/D2_U (e.g., in which a drain region is formed) on an upper side of the second pull-up transistor PU-2 may be electrically connected to a source/drain layer S/D1_L (e.g., in which a drain region is formed) on a lower side of the second pull-down transistor PD-2, and a second node therebetween corresponds to, for example, the node/Q in FIG. 1. A source/drain layer S/D5_U on an upper side of the second pass-gate transistor PG-2 may be electrically connected to the second node (for example, through a contact portion O2 schematically shown in FIG. 2, each contact portion O2 may be interconnected with each other through an interconnection line in a metal interconnection layer), and a source/drain layer S/D5_L on a lower side of the second pass-gate transistor PG-2 may be electrically connected to a second bit line (for example, the bit line/BL in FIG. 1) through a corresponding contact portion BL-2. Similarly, the source/drain layer S/D2_U on the upper side of the second pull-up transistor PU-2 and the source/drain layer S/D1_L on the lower side of the second pull-down transistor PD-2 may be in direct contact with or integrated with each other. The integrated source/drain layer may have a protruding portion PR3 protruding relative to the active region above, so that the corresponding contact portion O2 may be connected thereto. Similarly, the source/drain layer S/D5_L on the lower side of the second pass-gate transistor PG-2 may have a protruding portion PR4 protruding relative to the active region above, so that the contact portion BL-2 may be connected thereto.

A source/drain layer S/D4_L on the lower side of the first pull-up transistor PU-1 and a source/drain layer S/D2_L on the lower side of the second pull-up transistor PU-2 may be electrically connected to each other. For example, the source/drain layer S/D4_L on the lower side of the first pull-up transistor PU-1 and the source/drain layer S/D2_L on the lower side of the second pull-up transistor PU-2 may be provided on a base BS and may be integrated with the base BS. A power supply voltage V_{DD} may be applied through a contact portion VDD connected to the base BS.

In addition, the source/drain layer S/D3_U on the upper side of the first pull-down transistor PD-1 and the source/drain layer S/D1_U on the upper side of the second pull-down transistor PD-2 may be electrically connected to each other, for example, a low voltage V_{SS} may be applied through contact portions VSS respectively connected thereto.

The active region of each of the first pull-up transistor PU-1, the first pull-down transistor PD-1, the second pull-up transistor PU-2, and the second pull-down transistor PD-2 may extend in the first direction (e.g., x-direction), so that it may be in a linear shape extending in the first direction in a top view, as shown in FIG. 3(c). In addition, the active regions of the stacked first pull-up transistor PU-1 and first pull-down transistor PD-1, and the active regions of the stacked second pull-up transistor PU-2 and second pull-down transistor PD-2, may be spaced apart from each other in the second direction (e.g., y-direction), and the base BS extends therebetween in the second direction.

The first protruding portion PRI may protrude in the first direction on a side close to the first pass-gate transistor PG-1, so that the contact portion 01 connected to the first protruding portion PRI and the contact portion 01 connected to the source/drain layer S/D6_U on the upper side of the first pass-gate transistor PG-1 may be close to each other to facilitate interconnection with each other. Similarly, the third protruding portion PR3 may protrude in the first direction on a side close to the second pass-gate transistor PG-2, so that the contact portion 02 connected to the third protruding portion PR3 and the contact portion O2 connected to the source/drain layer S/D5_U on the upper side of the second pass-gate transistor PG-2 may be close to each other to facilitate interconnection with each other.

In the examples shown in FIG. 2, FIG. 3(a), and FIG. 3(b), the active region of each of the first pass-gate transistor PG-1 and the second pass-gate transistor PG-2 extends in the first direction, so that it may be in a linear shape extending in the first direction in the top view. However, the present disclosure is not limited to this. For example, referring to FIG. 3(c), the active region of each of the first pass-gate transistor PG-1 and the second pass-gate transistor PG-2 may have a second portion extending from a first portion in the second direction, so that it may be in a broken linear shape in the top view. The active region of each transistor may be in a shape of a rectangular ring as a whole in the top view (the first pass-gate transistor PG-1 and the second pass-gate transistor PG-2 are respectively located at diagonal corners of the rectangular ring), which will be further described in detail below.

The first portion of the active region of the first pass-gate transistor PG-1 may be spaced apart from (with an isolation trench therebetween) and aligned with the active regions of the stacked first pull-up transistor PU-1 and first pull-down transistor PD-1 in the first direction. Similarly, the first portion of the active region of the second pass-gate transistor PG-2 may be spaced apart from (with an isolation trench therebetween) and aligned with the active regions of the stacked second pull-up transistor PU-2 and second pull-down transistor PD-2 in the first direction.

According to embodiments of the present disclosure, the source/drain layer of each transistor may protrude relative to the channel layer in a lateral direction, so as to define a gate space self-aligned to the channel layer for accommodating the gate stack. For example, for the first pull-up transistor PU-1, the first pull-down transistor PD-1, the second pull-up transistor PU-2, and the second pull-down transistor PD-2 whose active regions extend in the first direction, their respective lower source/drain layers and upper source/drain layers may protrude towards two sides relative to the channel layer in the second direction. For the active regions of the first pass-gate transistor PG-1 and the second pass-gate transistor PG-2, in the first portion extending in the first direction, the corresponding lower source/drain layers and upper source/drain layers may protrude towards two sides relative to the channel layer in the second direction; in the second portion (if it exists) extending in the second direction, the corresponding lower source/drain layers and upper source/drain layers may protrude towards two sides relative to the channel layer in the first direction. Therefore, for each transistor, a gate space is defined on opposite sides of the channel layer between the corresponding lower source/drain layers and upper source/drain layers.

The gate stack may be formed in the gate space in a self-aligned manner.

As shown in FIG. 3 b), the gate stack of the first pull-up transistor PU-1 may include portions GA4-1 and GA4-2 between the lower source/drain layer S/D4_L and the upper source/drain layer S/D4_U, and on opposite sides of the channel layer CH4, respectively. These two portions GA4-1 and GA4-2 may sandwich the channel layer CH4. The portions GA4-1 and GA4-2 of the gate stack of the first pull-up transistor PU-1 may be electrically connected to each other through a first connection portion CP1. The gate stack of the first pull-down transistor PD-1 may include portions GA3-1 and GA3-2 between the lower source/drain layer S/D3_L and the upper source/drain layer S/D3_U, and on opposite sides of the channel layer CH3, respectively. These two portions GA3-1 and GA3-2 may sandwich the channel layer CH3. The portions GA3-1 and GA3-2 of the gate stack of the first pull-down transistor PD-1 may be electrically connected to each other through the first connection portion CP1.

The first connection portion CPI may extend from one side to the other side in the second direction across the stacked first pull-up transistor PU-1 and first pull-down transistor PD-1, so that not only the gate stack portions on the two sides may be electrically connected to each other, but also the gate stacks of the first pull-up transistor PU-1 and the first pull-down transistor PD-1 may be electrically connected to each other. The first connection portion CP1 may be integrated with a gate conductor in the gate stack. The gate stacks of the first pull-up transistor PU-1 and the first pull-down transistor PD-1 may be electrically connected to the second node (e.g., the node/Q in FIG. 1) through the contact portion 02 connected to the first connection portion CP1.

Similarly, the gate stack of the second pull-up transistor PU-2 may include portions GA2-1 and GA2-2 between the lower source/drain layer S/D2_L and the upper source/drain layer S/D2_U, and on opposite sides of the channel layer CH2, respectively. These two portions GA2-1 and GA2-2 may sandwich the channel layer CH2. The portions GA2-1 and GA2-2 of the gate stack of the second pull-up transistor PU-2 may be electrically connected to each other through a second connection portion CP2. The gate stack of the second pull-down transistor PD-2 may include portions GA1-1 and GA1-2 between the lower source/drain layer S/D1_L and the upper source/drain layer S/D1_U, and on opposite sides of the channel layer CHI, respectively. These two portions GA1-1 and GA1-2 may sandwich the channel layer CH1. The portions GA1-1 and GA1-2 of the gate stack of the second pull-down transistor PD-2 may be electrically connected to each other through the second connection portion CP2.

The second connection portion CP2 may extend from one side to the other side in the second direction across the stacked second pull-up transistor PU-2 and second pull-down transistor PD-2, so that not only the gate stack portions on the two sides may be electrically connected to each other, but also the gate stacks of the second pull-up transistor PU-2 and the second pull-down transistor PD-2 may be electrically connected to each other. The second connection portion CP2 may be integrated with a gate conductor in the gate stack. The gate stacks of the second pull-up transistor PU-2 and the second pull-down transistor PD-2 may be electrically connected to the first node (e.g., the node Q in FIG. 1) through the contact portion 01 connected to the second connection portion CP2.

For the convenience of electrical interconnection between the contact portions O1 and electrical interconnection between the contact portions O2, the first pass-gate transistor PG-1 may be provided on a first side (e.g., left side in the figure) of the stacked first pull-up transistor PU-1 and first pull-down transistor PD-1 in the first direction, and the second pass-gate transistor PG-2 may be provided on a second side (e.g., right side in the figure) opposite to the first side of the stacked second pull-up transistor PU-2 and second pull-down transistor PD-2 in the first direction. Therefore, the contact portions O1 may be disposed close to each other, and the contact portion 02 may be disposed close to each other, so as to facilitate their respective electrical interconnections.

Similarly, the gate stack of the first pass-gate transistor PG-1 may include portions GA6-1 and G6-2 between the lower source/drain layer S/D6_L and the upper source/drain layer S/D6_U, and on opposite sides of the channel layer CH6, respectively. These two portions GA6-1 and GA6-2 may sandwich the channel layer CH6. The portions GA6-1 and GA6-2 of the gate stack of the first pass-gate transistor PG-1 may be electrically connected to each other through a third connection portion CP3.

The third connection portion CP3 may extend from one side to the other side across the first pass-gate transistor PG-1 (e.g., extending from one side to the other side in the second direction across the first portion of the active region; or extending from one side to the other side in the first direction across the second portion of the active region), thereby electrically connecting the gate stack portions on the two sides to each other. The gate stack of the first pass-gate transistor PG-1 may be electrically connected to the word line (e.g., the word line WL shown in FIG. 1) through a contact portion WL-1 connected to the third connection portion CP3.

Similarly, the gate stack of the second pass-gate transistor PG-2 may include portions GA5-1 and G5-2 between the lower source/drain layer S/D5_L and the upper source/drain layer S/D5_U, and on opposite sides of the channel layer CH5, respectively. These two portions GA5-1 and GA5-2 may sandwich the channel layer CH5. The portions GA5-1 and GA5-2 of the gate stack of the second pass-gate transistor PG-2 may be electrically connected to each other through a fourth connection portion CP4.

The fourth connection portion CP4 may extend from one side to the other side across the second pass-gate transistor PG-2 (e.g., extending from one side to the other side in the second direction across the first portion of the active region; or extending from one side to the other side in the first direction across the second portion of the active region), so that the gate stack portions on the two sides may be electrically connected to each other. The gate stack of the second pass-gate transistor PG-2 may be electrically connected to the word line (e.g., the word line WL shown in FIG. 1) through a contact portion WL-2 connected to the fourth connection portion CP4.

It can be seen that each transistor has a structure in which the channel layer is sandwiched by the gate stack on opposite sides, so that a vertical gate-all-around field-effect transistor (V-GAAFET) configuration may be obtained. The V-GAAFET configuration may have advantages such as low parasitic capacitance, high read and write controllability, low operating voltage, and low stable leakage performance.

Transistors disposed in the same layer may be substantially coplanar with each other, for example, their respective lower source/drain layers may be substantially coplanar with each other, their respective channel layers may be substantially coplanar with each other, and their respective upper source/drain layers may be substantially coplanar with each other.

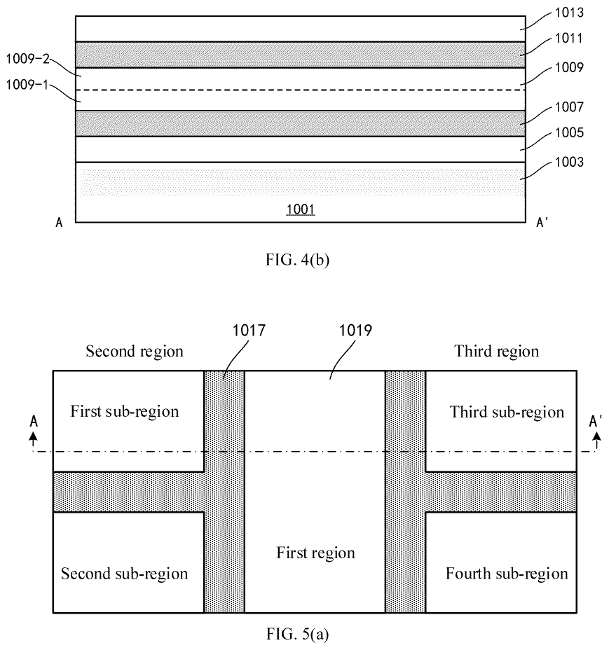

FIG. 4(a) to FIG. 35(c) schematically show some stages in a process of manufacturing an SRAM cell according to an embodiment of the present disclosure.

In the following description, a material of each layer is listed. However, these are merely examples. The material of each layer is primarily determined according to the function of the layer (for example, a semiconductor material is used to provide an active region, a dielectric material is used to provide gap filling and electrical isolation, etc.) and required etching selectivity. In the description, in some cases, it may not be explicitly stated that a material of a certain layer has etching selectivity relative to materials of other layers, or only the “required etching selectivity” is simply mentioned. Such “required etching selectivity” may at least partially be determined according to related etching process.

As shown in FIG. 4(a) and FIG. 4(b) (which are a top view, and a cross-sectional view along line AA′, respectively), a substrate 1001 is provided. The substrate 1001 may be in various forms. The substrate 1001 may include a semiconductor material, for example but not limited to a bulk semiconductor material such as a bulk Si, a semiconductor-on-insulator (SOI), a compound semiconductor material such as SiGe, and the like. In the following description, for ease of explanation, a bulk Si substrate such as a silicon wafer is taken as an example for explanation. In the substrate 1001, a well region 1003 may be formed as required, for example, by implanting impurities. In an example of which the p-type transistor is provided in the lower layer, the implanted impurities may be n-type impurities.

On the substrate 1001, an active material layer may be provided. For example, a first group including a first source/drain layer 1005, a channel defining layer 1007 and a second source/drain layer 1009-1, and a second group including a first source/drain layer 1009-2, a channel defining layer 1011 and a second source/drain layer 1013 may be sequentially formed by epitaxial growth. Through doping in situ during growth or implanting impurities after growth, these layers may have required conductivity. In the following example, the active layer of the first group (which may also be referred to as “lower active layer”) may be used to form the p-type transistor, and the active layer of the second group (which may also be referred to as “upper active layer”) may be used to form the n-type transistor. However, the present disclosure is not limited to this.

Adjacent layers in each semiconductor material layer formed on the substrate 1001 may have etching selectivity relative to each other, except for the second source/drain layer 1009-1 of the first group and the first source/drain layer 1009-2 of the second group, which may have no etching selectivity or low etching selectivity relative to each other, since in subsequent processing, they are almost processed as the same layer except for being doped to different conductivity types to serve as a source/drain layer of the p-type transistor and a source/drain layer of the n-type transistor, respectively. In fact, they may be formed by the same semiconductor layer (different types of doping may be applied to lower and upper portions of the semiconductor layer, respectively), and may not have actual physical interfaces between each other (and therefore uniformly shown as 1009 in subsequent figures for convenience). In addition, the first source/drain layer 1005 and the second source/drain layer 1009-1 in the first group may include the same material, and similarly, the first source/drain layer 1009-2 and the second source/drain layer 1013 in the second group may include the same material.

According to embodiments of the present disclosure, these semiconductor material layers may include an alternate stack of Si and SiGe. For example, in a case that the substrate 1001 is Si, each source/drain layer 1005, 1009, 1013 may include Si with a thickness of about 80 nm to 300 nm, and each channel defining layer 1007, 1011 may include SiGe (for example, an atomic percentage of Ge is about 20%) with a thickness of about 5 nm to 100 nm.

In a specific example, the following stack may be formed on the substrate 1001: a p+doped Si layer (1005) with a thickness of about 300 nm/a SiGe layer (1007) with a thickness of about 60 nm/a p+doped Si layer (1009-1) with a thickness of about 100 nm, an intrinsic Si layer (1009-2) with a thickness of about 100 nm/a SiGe layer (1011) with a thickness of about 60 nm/an intrinsic Si layer (1013) with a thickness of about 120 nm. In this example, the source/drain layers in the first group are doped in situ during growth (p+doped Si layer) to subsequently form the p-type transistor, and the source/drain layers in the second group are not doped during growth (intrinsic Si layer).

An isolation process, such as a Shallow Trench Isolation (STI) process, may be performed to define an active region in the stack.

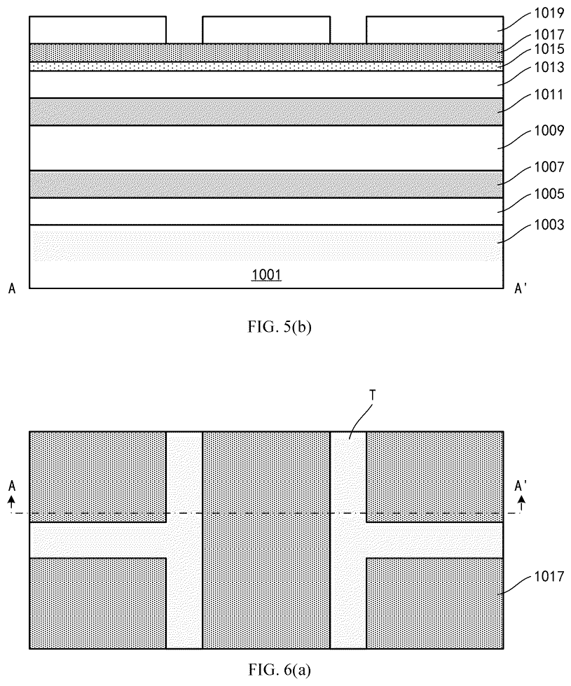

For example, as shown in FIG. 5(a) and FIG. 5(b) (which are a top view, and a cross-sectional view along line AA′, respectively), a pad oxide layer 1015 (e.g., silicon oxide) and a nitride layer 1017 (e.g., silicon nitride) may be sequentially formed on the stack by, for example, deposition. The nitride layer 1017 may be used as a hard mask. A photoresist 1019 may be coated on the nitride layer 1017. The photoresist 1019 may be patterned through a photolithography process to block the regions to be defined as the active regions and expose the regions between the active regions. These exposed regions may then be etched to form a trench (isolation trench) in the stack.

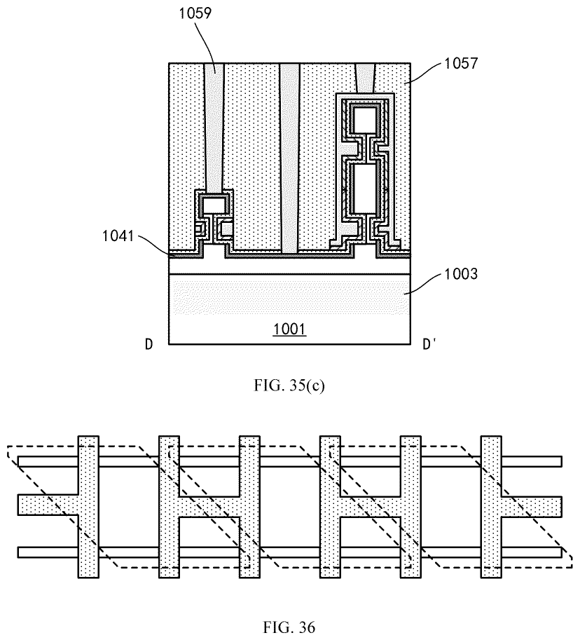

The photoresist 1019 may be patterned as such a pattern that covers a first region where the first pull-up transistor, the first pull-down transistor, the second pull-up transistor, and the second pull-down transistor are to be formed; in the second region spaced apart from the first region on the first side (e.g., left side in the figure) of the first region in the first direction (e.g., x-direction), covers the first sub-region and the second sub-region respectively, the first sub-region and the second sub-region being spaced apart from each other in the second direction (e.g., y-direction); and in the third region spaced apart from the first region on the second side (e.g., right side in the figure) of the first region in the first direction (e.g., x-direction), covers the third sub-region and the fourth sub-region respectively, the third sub-region and the fourth sub-region being spaced apart from each other in the second direction (e.g., y-direction). The second region and the third region may have substantially the same pattern. When forming a memory cell array, the first region and the second/third region (which are substantially the same) may be alternately and repeatedly disposed (with reference to FIG. 36).

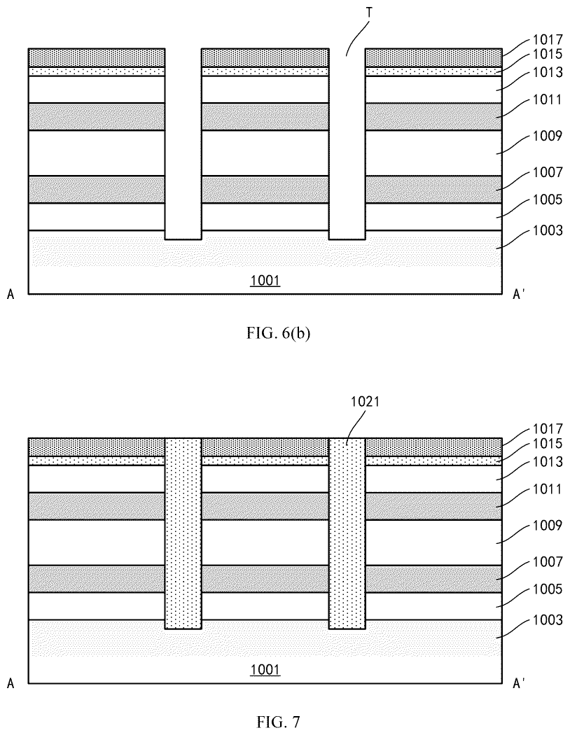

As shown in FIG. 6(a) and FIG. 6(b) (which are a top view, and a cross-sectional view along line AA′, respectively), an isolation trench T may be formed in the stack by anisotropic etching, such as Reactive Ion Etching (RIE) in the vertical direction (e.g., z-direction). As shown in the figures, the isolation trench T has a pattern defined by the photoresist 1019, and may be between the first region and the second region, between the first region and the third region, between the first sub-region and the second sub-region, and between the third sub-region and the fourth sub-region. The isolation trench T may have a substantially uniform width and may have a substantially uniform depth. The bottom of the isolation trench T may enter the well region 1003, thereby separating the active layers in the stack from each other and thus electrically isolating the active layers in the stack from each other. After forming the isolation trench T, the photoresist 1019 may be removed.

As shown in FIG. 7 (a cross-sectional view along line AA′), a filling material 1021 may be formed in the isolation trench T formed in this way. For example, the filling material 1021 may be formed by depositing an oxide and performing planarization process such as Chemical Mechanical Polishing (CMP) on the deposited oxide, and CMP may stop at the nitride layer 1017. The filling material 1021 may fill a gap in the stack, so as to facilitate subsequent processing of the stack.

The stack may be further patterned in the active region defined as described above, so as to obtain a required pattern. For the convenience of subsequent patterning, as shown in FIG. 8 (a cross-sectional view along line AA′), the nitride layer 1017 used as a hard mask may be removed by, for example, planarization process such as CMP (in order to subsequently form other hard masks used to assist in patterning). In the planarization process, the filling material 1021 may be reduced in height. The planarization process may leave the pad oxide layer 1015, and the top surfaces of the filling material 1021 and the pad oxide layer 1015 may be substantially flat.

The number of layers of the hard mask used to assist in patterning and the material of each layer may vary depending on the process. In the disposing of the hard mask, a spacer may be used to achieve finer control of the pattern size.

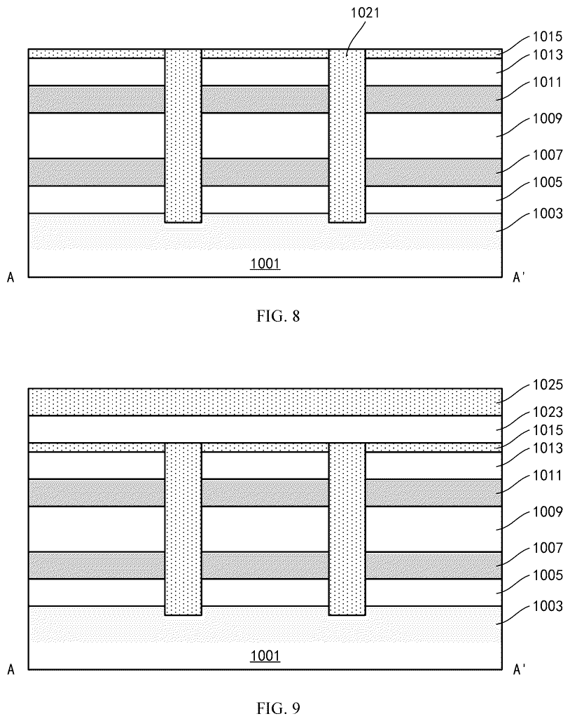

As described above, the active layer may have, for example, a rectangular ring shape as a whole in the top view. According to embodiments, the pattern may be defined by the spacer. In order to form the spacer, as shown in FIG. 9 (a cross-sectional view along line AA′), a mandrel layer 1023 may be formed on the pad oxide layer 1015 by, for example, deposition. The mandrel layer 1023 may include, for example, polycrystalline silicon and may have a thickness of, for example, about 450 nm. The mandrel layer 1023 may then be patterned, for example, into a rectangle to provide a vertical sidewall for forming the spacer. In addition, on the mandrel layer 1023, a mask layer 1025 may be formed by, for example, deposition. The mask layer 1025 may include, for example, an oxide and may have a thickness of, for example, about 350 nm. The mask layer 1025 may then assist in patterning inner and outer sides of the spacer separately.

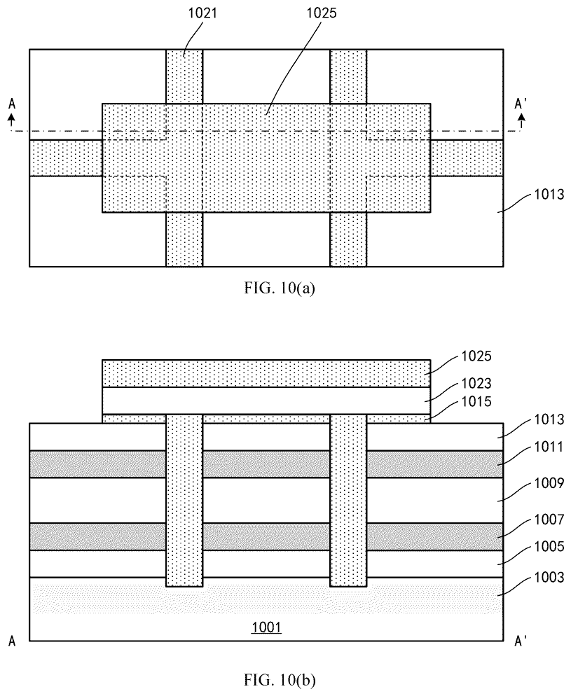

As shown in FIG. 10(a) and FIG. 10(b) (which are a top view, and a cross-sectional view along line AA′, respectively), the mask layer 1025 and the mandrel layer 1023 (and the pad oxide layer 1015) may be patterned, for example, into a rectangle by anisotropic etching such as RIE in the vertical direction. The rectangle may have two edges extending in the first direction and two edges extending in the second direction. The edges of the rectangle may be set such that four corners of the rectangle are located in the first sub-region to the fourth sub-region, respectively. In the RIE, a recipe with etching selectivity relative to the source/drain layer 1013 (in this example, Si) may be selected.

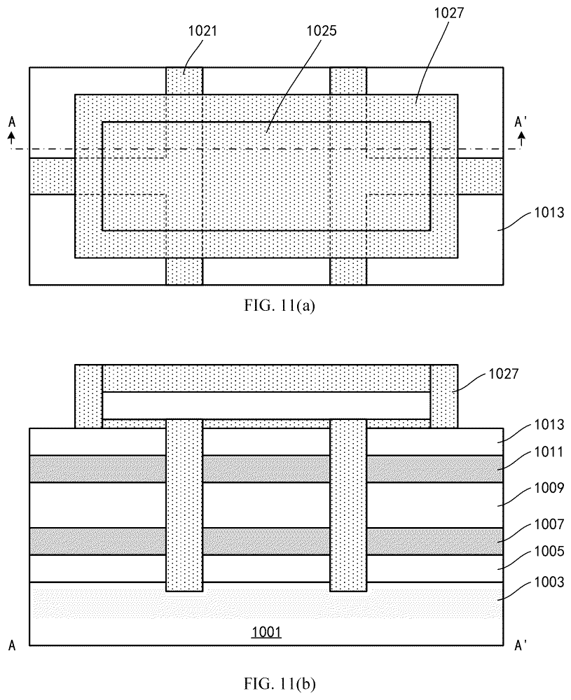

As shown in FIG. 11(a) and FIG. 11(b) (which are a top view, and a cross-sectional view along line AA′, respectively), a spacer 1027 may be formed on the sidewall of the rectangular mandrel layer 1023 (and the mask layer 1025) through a spacer formation process. The spacer formation process may include depositing a layer of oxide, for example, about 1500 Å on the above-mentioned structure in a substantially conformal manner, and performing anisotropic etching such as RIE in the vertical direction on the deposited oxide layer to remove a laterally extending portion thereof and leave a vertically extending portion thereof. Therefore, the spacer 1027 is formed into a closed pattern around a periphery of the mandrel layer 1023. In this example, the spacer 1027 is in a shape of a rectangular ring, thereby including two edges extending in the first direction and two edges extending in the second direction, and each of the edges may have a substantially uniform thickness. In the rectangular ring pattern, the two edges extending in the first direction may define active regions for the stacked first pull-up transistor and first pull-down transistor and the stacked second pull-up transistor and second pull-down transistor respectively in the first region. The corner in the first sub-region may define the active region for the first pass-gate transistor in the first sub-region. The corner in the fourth sub-region may define the active region for the second pass-gate transistor in the fourth sub-region.

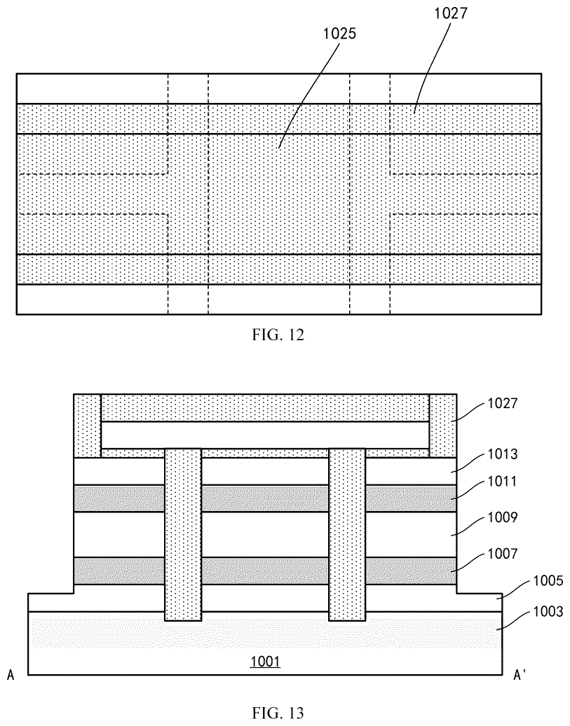

The pattern of the spacer 1027 changes with the pattern of the mandrel layer 1023. The pattern of the mandrel layer 1023 and the pattern of the spacer 1027 may be changed differently according to the device layout design. An example is shown in FIG. 12. As shown in FIG. 12 (a cross-sectional view along line AA′), the mandrel layer 1023 (and the mask layer 1025) may be formed in a strip shape extending in the first direction, and thus the spacer 1027 may be in a strip shape extending in the first direction. In this case, the active regions defined by the spacer 1027 in the first sub-region and the fourth sub-region for the first pass-gate transistor and the second pass-gate transistor may be in a linear shape in the top view, as previously described in combination with FIG. 2, FIG. 3(a), and FIG. 3(b) (the schematic array layout in FIG. 36 is also based on this configuration).

Hereinafter, the spacer 1027 being in a rectangular ring shape is taken as an example for description.

The spacer 1027 may be used to define the pattern of the active region to include the nanosheet extending along the edge of the spacer 1027. In addition, the mask layer 1025 covers an inner region of the spacer 1027.

The active layer (of which the outer side) may be patterned using the spacer 1027 and the mask layer 1025. For example, as shown in FIG. 13 (a cross-sectional view along line AA′), each of the active layers 1013, 1011, 1009, 1007, and 1005 may be sequentially etched by, for example, RIE in the vertical direction. The RIE may stop in the first source/drain layer 1005 in the first group. In this example, on the outer side of the spacer 1027, the first source/drain layer 1005 may be left with a certain thickness, so that a protruding portion may be subsequently formed (e.g., forming a second protruding portion PR2 as described above in the first sub-region and forming a fourth protruding portion PR4 as described above in the fourth sub-region).

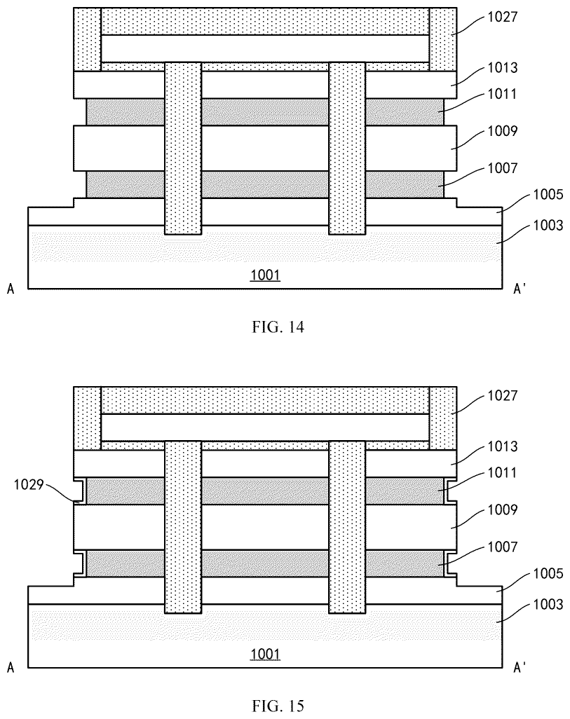

In order to form a self-aligned gate stack, for example, as shown in FIG. 14 (a cross-sectional view along line AA′), the channel defining layers 1007 and 1011 may be further selectively etched to be recessed in the lateral direction relative to the source/drain layers on the upper and lower sides, and such recess defines a gate space between the source/drain layers on the upper and lower sides. After etching, the channel defining layers 1007 and 1011 may still have substantially vertical sidewalls. Selective etching may use an Atomic Layer Etching (ALE) method to precisely control an etching depth.

In addition, the etching depth may be controlled, for example, to be smaller than a line width of the spacer 1027, so that the channel defining layers 1007 and 1011 will not be recessed into the inner side of the spacer 1027 after being etched (i.e., the sidewalls of the channel defining layers 1007 and 1011 may overlap with the spacer 1027 in the vertical direction after etching). In this way, a self-aligned gate space may be defined on the inner side of the spacer 1027, so as to facilitate the formation of V-GAAFET.

As shown in FIG. 15 (a cross-sectional view along line AA′), the channel layer 1029 may be grown on the vertical sidewalls of the channel defining layers 1009 and 1015 by, for example, selective epitaxial growth. The thickness of the grown film may be controlled to, for example, about 3 nm to 20 nm, such that the gate space left between the source/drain layers is not fully filled due to the recess of the channel defining layer after forming the channel layer 1029. Since the channel layer 1029 is formed by separate epitaxial growth, the film thickness and crystal quality thereof may be well controlled.

Here, the channel layer 1029 is shown as being formed only in the gate space (especially on the sidewalls of the channel defining layers 1007, 1011), but the channel layer 1029 may also be formed on the exposed surfaces of other semiconductor material layers. The portions of the channel layer 1029 on the sidewalls of the channel defining layers 1007 and 1011 may subsequently serve as the channel of the transistor (and thus the channel length of the transistor may be determined by the thickness of the channel defining layer, and the channel defining layer is formed by epitaxial growth, so that the thickness thereof may be well controlled), and the remaining portions do not affect the subsequent process or the operation of the transistor and thus are not shown for convenience.

The material of the channel layer 1029 may be selected according to the device design. For example, the channel layer 1029 may include a semiconductor material (in this example, Si) substantially the same as the source/drain layer. Alternatively, the channel layer 1029 may include a semiconductor material different from the source/drain layer, such as SiGe, so as to improve device performance (e.g., improve carrier mobility).

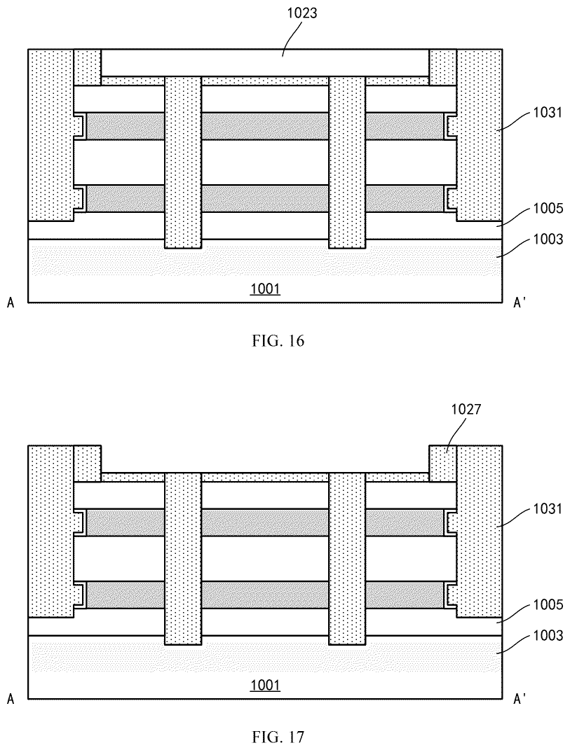

At this point, the pattern of the active layer has been substantially defined on the outer side of the spacer 1027. Next, the pattern of the active layer may be defined on the inner side of the spacer 1027. For this purpose, a shielding layer may be formed on the substrate, so as to shield outer sides of various structures on the substrate. For example, as shown in FIG. 16 (a cross-sectional view along line AA′), a shielding layer 1031 may be formed by depositing, for example, an oxide and performing planarization process such as CMP on the deposited oxide. The planarization process may stop at the mandrel layer 1023. Next, the inner side of the active material layer may be patterned.

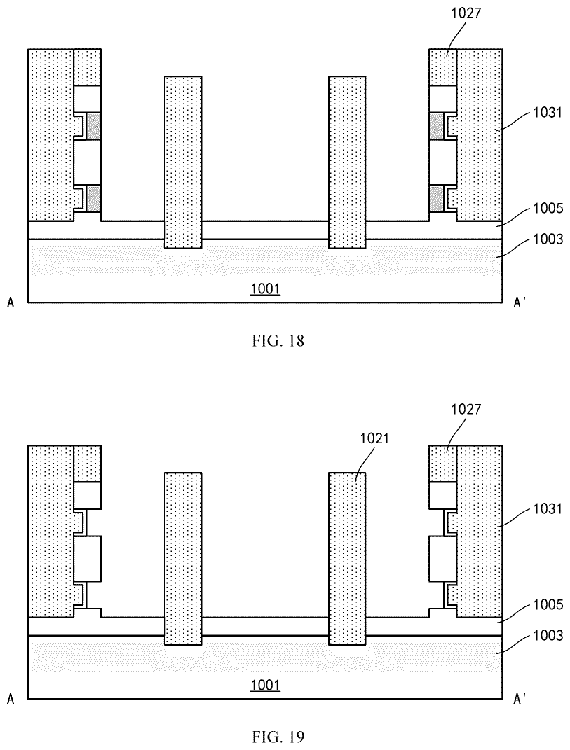

For example, as shown in FIG. 17 (a cross-sectional view along line AA′), the mandrel layer 1023 exposed due to the planarization process may be removed by selective etching, such as wet etching using TMAH solution. Then, as shown in FIG. 18 (a cross-sectional view along line AA′), anisotropic etching may be sequentially performed on each layer on the substrate 1001 on the inner side of the spacer 1027 by, for example, RIE in the vertical direction. Similar to the etching on the outer side described above in combination with FIG. 13, RIE may stop in the first source/drain layer 1005 of the first group. In this example, on the inner side of the spacer 1027, the first source/drain layer 1005 may be left with a certain thickness (which may be substantially the same as the thickness left on the outer side of the spacer 1027), so that a base BS may subsequently be formed in the first region.

The channel defining layers 1007 and 1011 are exposed and thus may be removed. For example, as shown in FIG. 19 (a cross-sectional view along line AA′), the channel defining layers 1007 and 1011 may be selectively etched, such as wet etched, to be removed. Due to the removal of the channel defining layers, a gate space self-aligned with the channel layer is defined between the source/drain layers on the inner side of the spacer 1027.

In this example, the doping of the n-type transistor has not been performed (as described above, a source/drain layer of intrinsic Si is formed in the active layers of the second group). In this case, the doping of the n-type transistor may be performed.

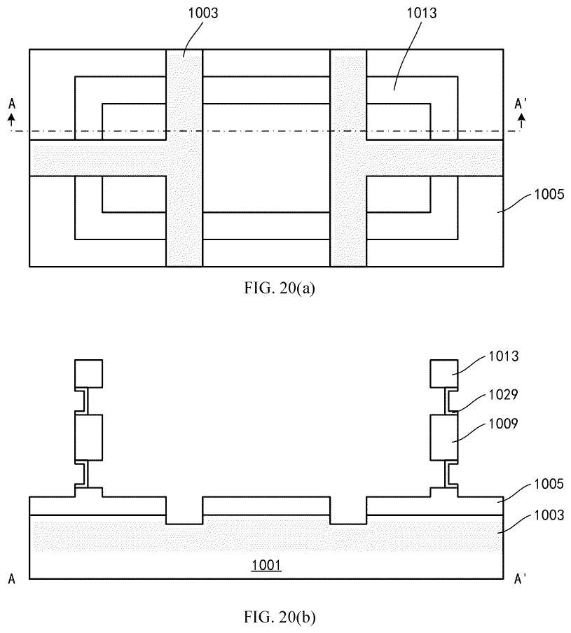

For example, as shown in FIG. 20(a) and FIG. 20(b) (which are a top view, and a cross-sectional view along line AA′, respectively), the filling layer 1021, the spacer 1027, and the shielding layer 1031 may be stripped by selective etching, such as wet etching, so as to fully expose each active layer.

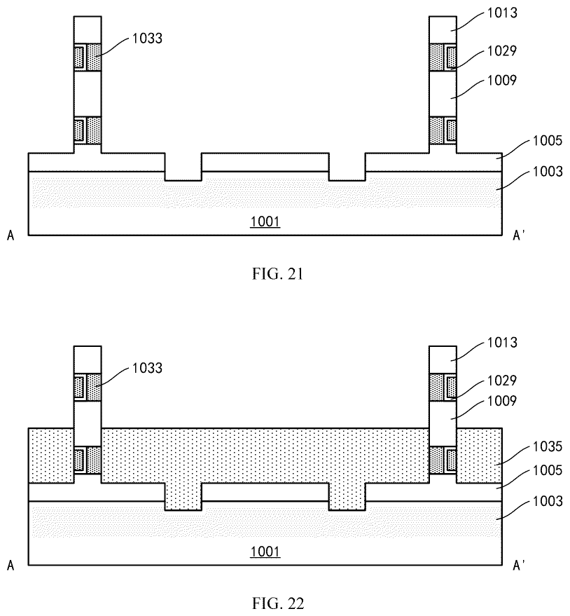

In addition, in order to avoid subsequent processing affecting the channel layer or the gate space, as shown in FIG. 21 (a cross-sectional view along line AA′), a sacrificial gate 1033 may be filled in the gate space. For example, the sacrificial gate 1033 filled in the gate space in a self-aligned manner may be formed by sequentially forming an oxide with a thickness of about 5 nm and a nitride with a thickness of about 10 nm to 100 nm by deposition, and performing anisotropic etching on the deposited nitride and oxide by RIE in the vertical direction.

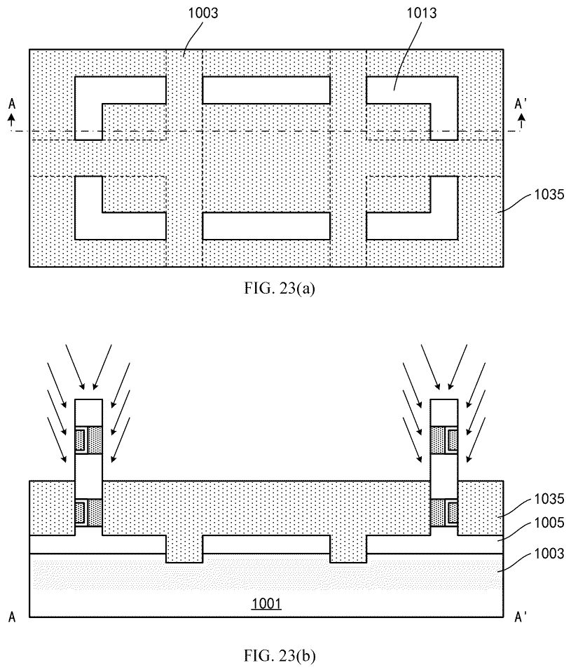

As shown in FIG. 22 (a cross-sectional view along line AA′), a shielding layer 1035 may be formed on the substrate 1001 to shield the active layers of the first group and expose the active layers of the second group. For example, the shielding layer 1035 may be formed by depositing an oxide, performing planarization process such as CMP on the deposited oxide, and etching back on the planarized oxide. A top surface of the shielding layer 1035 after etching back may be between the top and bottom surfaces of the source/drain layer 1009, especially at or near an interface between a lower portion that has been (in situ) doped and an upper portion that has not been (intentionally) doped in the source/drain layer 1009.

In this example, the four transistors in the lower layer are formed as the p-type devices. However, the present disclosure is not limited to this. For example, the first pass-gate transistor and the second pass-gate transistor may be formed as the n-type devices. In this case, the shielding layer 1035 may be patterned to expose the first sub-region and the fourth sub-region of the active region.

As shown in FIG. 23(a) and FIG. 23(b) (which are a top view, and a cross-sectional view along line AA′, respectively), the exposed active layer may be n-type doped by ion implantation. There are various processes in the art for performing source/drain ion implantation, which will not be repeated herein.

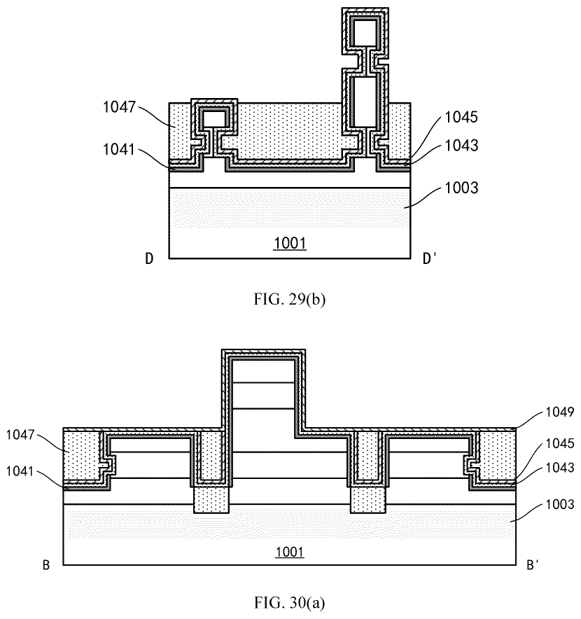

In this example, the active layers of the second group are not doped in situ during growth, but are additionally doped based on the shielding layer 1035 by, for example, ion implantation. This may have the following advantages. Based on the shielding layer 1035, especially its top surface position, the interface between n-type doping and p-type doping may be substantially determined. In subsequent processes, especially processes (e.g., processes for forming different work function adjustment layers) that require separate processing of the upper layer device and the lower layer device, other shielding layers (e.g., with reference to 1047 shown in FIG. 29(a) and FIG. 29 b)) may be formed based on process parameters in the process of forming the shielding layer 1035. A top surface of such shielding layer may be at or near the interface between n-type doping and p-type doping, so that the upper layer device may be well processed while shielding the lower layer device.

Previously, the active layers are patterned on both the inner and outer sides of the spacer 1027 in the case of the presence of the spacer 1027. The spacer 1027 has been removed, and thus the portion of the active layer previously overlapping with the spacer 1027 in the vertical direction may be further patterned, so as to facilitate the manufacturing of subsequent electrical interconnection.

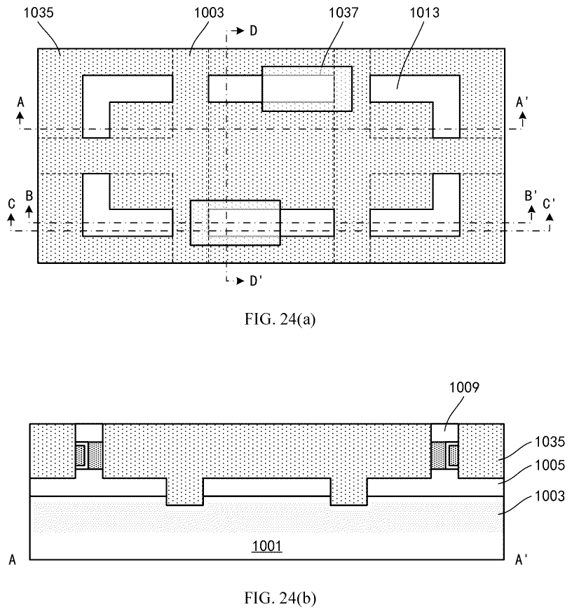

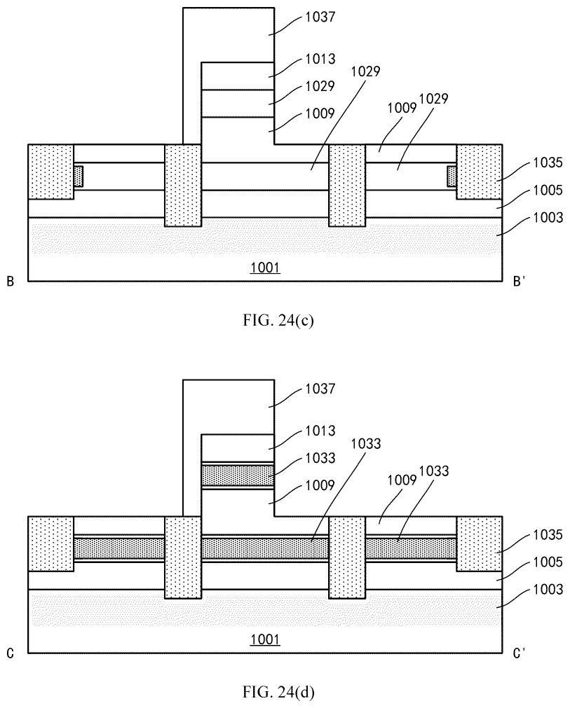

For example, as shown in FIG. 24(a), FIG. 24(b), FIG. 24(c), FIG. 24(d), and FIG. 24(e) (which are a top view, a cross-sectional view along line AA′, a cross-sectional view along line BB′, a cross-sectional view along line CC′, and a cross-sectional view along line DD′, respectively), a photoresist 1037 may be coated on the shielding layer 1035. The photoresist 1037 may be patterned through photolithography in such a pattern that covers the portion of the active layer that defines each of the active regions of the first pull-down transistor and the second pull-down transistor in the first region (in the top view, covering part of the length of each of the two linear shape portions in the first region), and expose the remaining portions of the active layer. The layout of the first pull-down transistor and the second pull-down transistor has been described in detail above in combination with FIG. 2 and FIG. 3(a) to FIG. 3(c), which will not be repeated herein.

The patterned photoresist 1037 may be used as an etching mask to selectively etch the active layer. Therefore, the portion of the active layer (for the n-type transistor) on the shielding layer 1035 that is not covered by the photoresist 1037 (together with the corresponding sacrificial gate) may be removed. After that, the photoresist 1037 may be removed.

In the first to fourth sub-regions, the active layers of the first group may be retained (in the first and fourth sub-regions, the active regions of the first pass-gate transistor and the second pass-gate transistor may be defined respectively; in the second and third sub-regions, the active regions of the pass-gate transistors in other SRAM cells may be defined). In addition, in the first region, the active layers of the first group may be retained (the active regions of the first pull-up transistor and the second pull-up transistor may be defined respectively), and the active layers of the second group (on a partial length of the linear shape pattern) may be partially retained (the active regions of the first pull-down transistor and the second pull-down transistor may be defined respectively), as shown in FIG. 24(c) and FIG. 24(d).

As described above, in the first region, the active layers of the first group may retain a partial length. On the one hand, this may expose the source/drain layer 1009, so as to fabricate the manufacturing of electrical interconnection (e.g., forming the first protruding portion PRI and the third protruding portion PR3 as described above). On the other hand, the size of the active layer of the first group, especially the channel layer therein (e.g. for n-type transistor), may be adjusted relative to the active layer of the second group, especially the channel layer therein (e.g. for p-type transistor). Therefore, the first width of the channel layer of the second group (e.g. for n-type transistor) in the first direction may be less than the second width of the channel layer of the first group (e.g. for p-type transistor) in the first direction. The channel width may be flexibly adjusted by controlling the process parameters. In addition, as described above, the channel length may be flexibly controlled by the thickness of the channel defining layer. Therefore, the driving capability of the transistor may be flexibly adjusted according to the device design.

At this point, the layout definition of the SRAM cell has been substantially completed. Next, a replacement gate process may be performed to complete the manufacturing of transistors, and interconnections between these transistors may be formed to complete the manufacturing of the SRAM cell.

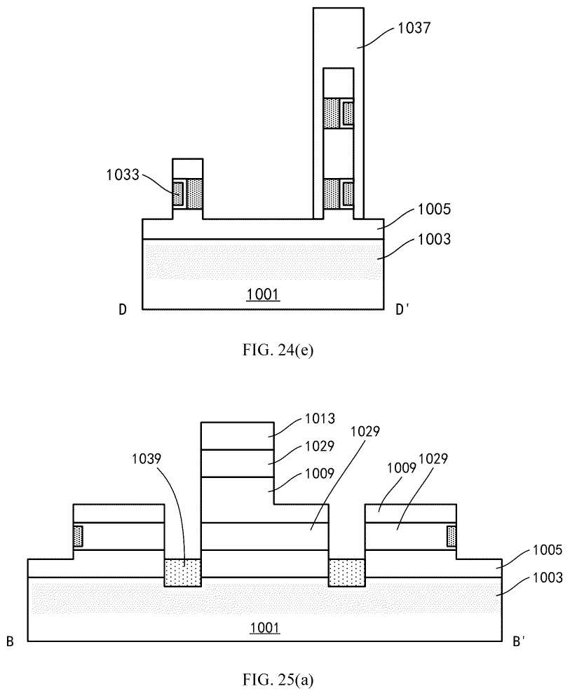

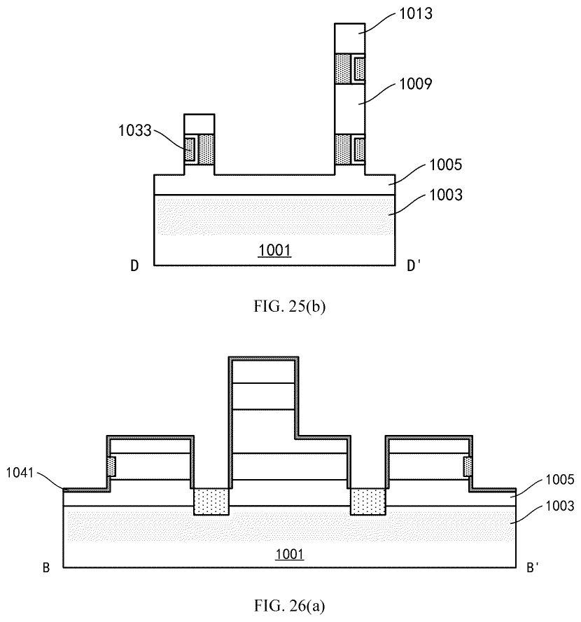

As shown in FIG. 25(a) and FIG. 25(b) (which are a cross-sectional view along line BB′, and a cross-sectional view along line DD′, respectively), the shielding layer 1035 may be etched back. The etching back depth may be controlled, so that the shielding layer 1035 remains in the isolation trench to form an isolation portion 1039, and each active layer is exposed.

In order to enhance contact and/or reduce resistance, siliconization may be performed on the source/drain layers.

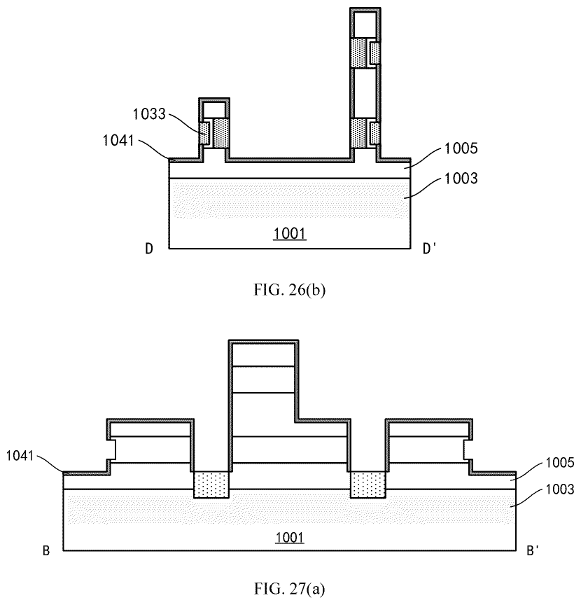

For example, as shown in FIG. 26(a) and FIG. 26(b) (which are a cross-sectional view along line BB′, and a cross-sectional view along line DD′, respectively), siliconization may be performed, so that the exposed source/drain layers may be at least partially or even completely siliconized, thereby forming a silicide layer 1041. The silicification may, for example, include depositing a metal such as NiPt alloy and performing a heat processing at a temperature of, for example, about 200° C. to 600° C., so as to react the deposited metal with semiconductor elements such as Si and/or Ge in the source/drain layer, thereby forming a compound of metal and semiconductor element, such as silicide, germanide, or silicide-germanide (hereinafter referred to as silicide). After that, unreacted excess metals may be removed.

It should be noted that although the silicide layer 1041 is shown as a thin layer here, some portions may be completely converted into silicide according to the size of a portion where a siliconization reaction occurs and the time when the siliconization reaction is performed.

Next, the replacement gate process may be performed.

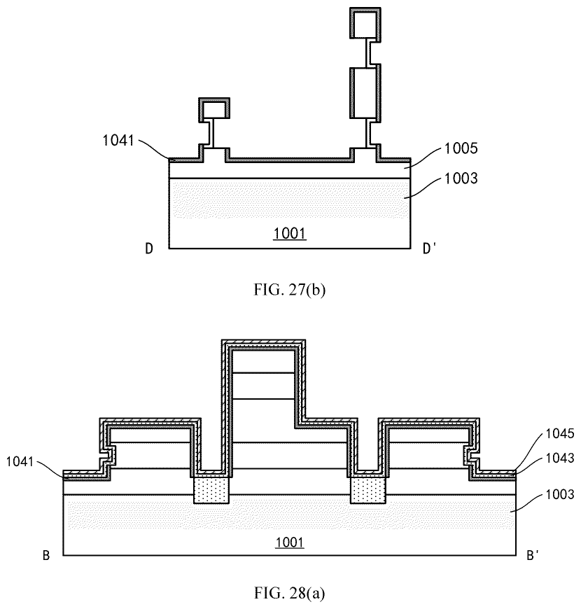

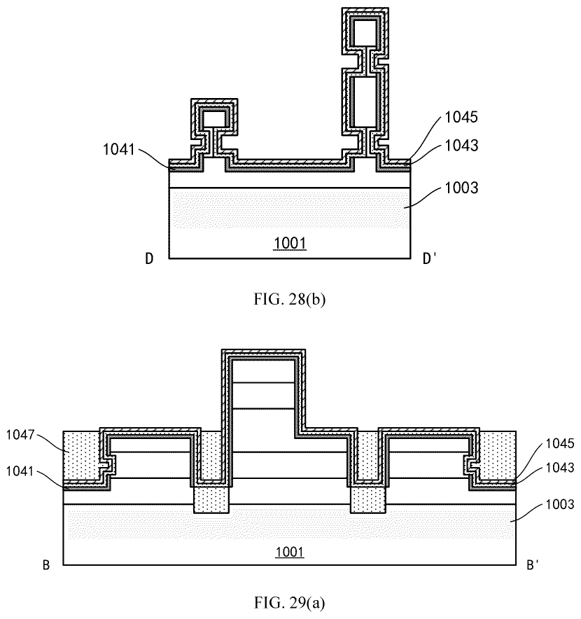

For example, as shown in FIG. 27(a) and FIG. 27(b) (which are a cross-sectional view along line BB′, and a cross-sectional view along line DD′, respectively), the sacrificial gate 1033 may be removed by selective etching. Therefore, the channel layer 1029 may be exposed. Then, as shown in FIG. 28(a) and FIG. 28(b) (which are a cross-sectional view along line BB′, and a cross-sectional view along line DD′, respectively), a gate dielectric layer 1043 and a work function adjustment layer 1045 may be sequentially formed by deposition, such as Atomic Layer Deposition (ALD). The gate dielectric layer 1043 may include a high-k gate dielectric such as HfO₂, and the work function adjustment layer 1045 may provide an equivalent work function suitable for p-type transistors. The gate dielectric layer 1043 and the work function adjustment layer 1045 may be formed in a substantially conformal manner.

In order to improve performance, different equivalent work functions may be provided for p-type transistors and n-type transistors, respectively, for example, with different work function adjustment layers.

For example, as shown in FIG. 29(a) and FIG. 29(b) (which are a cross-sectional view along line BB′, and a cross-sectional view along line DD′, respectively), a shielding layer 1047 may be formed in the manner of forming the shielding layer 1035 described above in combination with FIG. 22. A top surface of the shielding layer 1047 may be at or near the interface between different types of doping in the source/drain layer 1009.

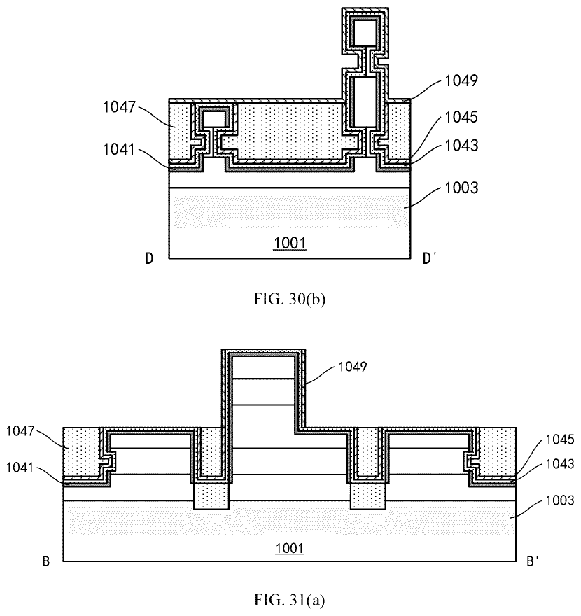

Then, as shown in FIG. 30(a) and FIG. 30(b) (which are a cross-sectional view along line BB′, and a cross-sectional view along line DD′, respectively), the work function adjustment layer 1045 exposed by the shielding layer 1047 may be removed by selective etching. In addition, another work function adjustment layer 1049 may be formed by, for example, deposition. The work function adjustment layer 1049 may provide an equivalent work function suitable for n-type transistors. The work function adjustment layer 1049 may be formed in a substantially conformal manner.

As further described below, various contact portions may be provided on the top surface of the active region. Currently, the work function adjustment layer 1049 extends on the top surface of the active region, which may cause undesired electrical short circuits between the subsequently formed contact portion and the work function adjustment layer 1049.

For this purpose, as shown in FIG. 31 a) and FIG. 31(b) (which are a cross-sectional view along line BB′, and a cross-sectional view along line DD′, respectively), at least the work function adjustment layer 1049 on the top surface of each active region may be removed by etching. Before etching, a protective layer 1051 such as an oxide may be formed in the gate space (in which the gate dielectric layer 1043 and the work function adjustment layer 1049 have been formed) of the n-type transistor in the above-described manner of forming the sacrificial gate, so as to prevent the work function adjustment layer on the surface of the channel layer from being damaged in the etching process. In the case of the presence of the protective layer 1051, anisotropic etching may be performed on the work function adjustment layer 1049 by, for example, RIE in the vertical direction, so as to remove the work function adjustment layer 1049 from the top surface of each active region (a vertically extending portion thereof may be at least partially retained).

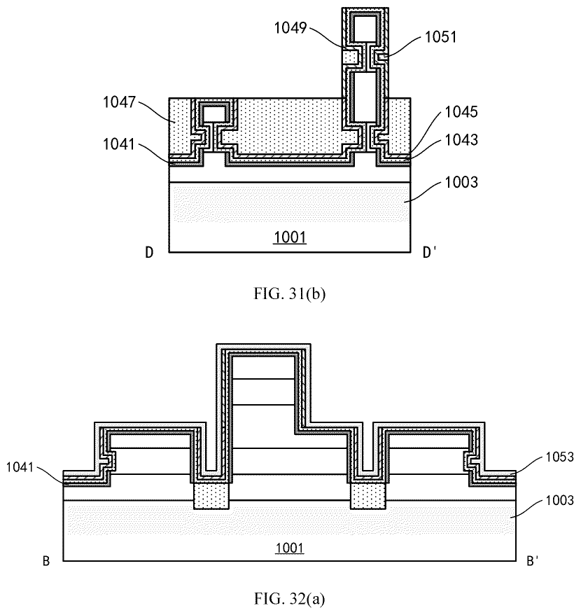

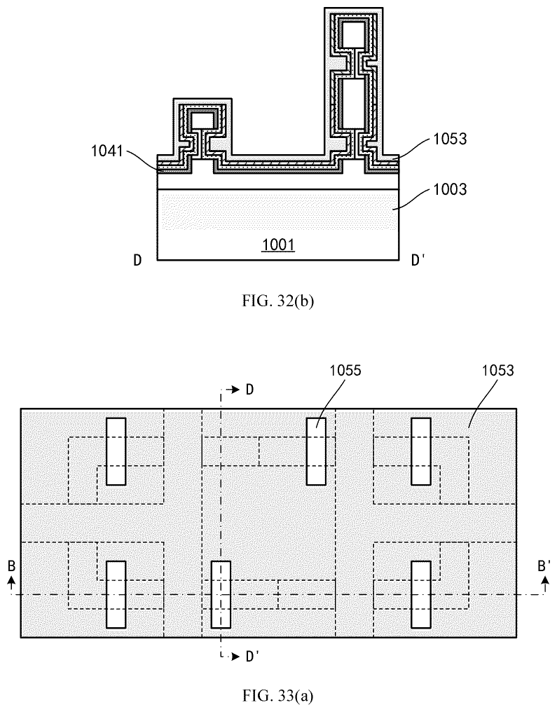

As shown in FIG. 32(a) and FIG. 32(b) (which are a cross-sectional view along line BB′, and a cross-sectional view along line DD′, respectively), the shielding layer 1047 and the protective layer 1051 may be removed by selective etching. In this example, they both include an oxide and may therefore be removed together by the same etching recipe. Then, a gate conductor layer 1053 (e.g. tungsten) may be formed by, for example, deposition. The gate conductor layer 1053 may be deposited in a substantially conformal manner, and the film thickness thereof may be controlled, so that the gate space may be fully filled.

The gate conductor layer 1053 and the work function adjustment layers 1045, 1049 may be patterned, so that, on the one hand, unnecessary conductive layers outside the gate space may be removed to avoid problems of electrical short circuits and the like, and on the other hand, interconnection structures of the gate stack (e.g., the aforementioned first to fourth connection portions CP1, CP2, CP3, CP4) may be formed.

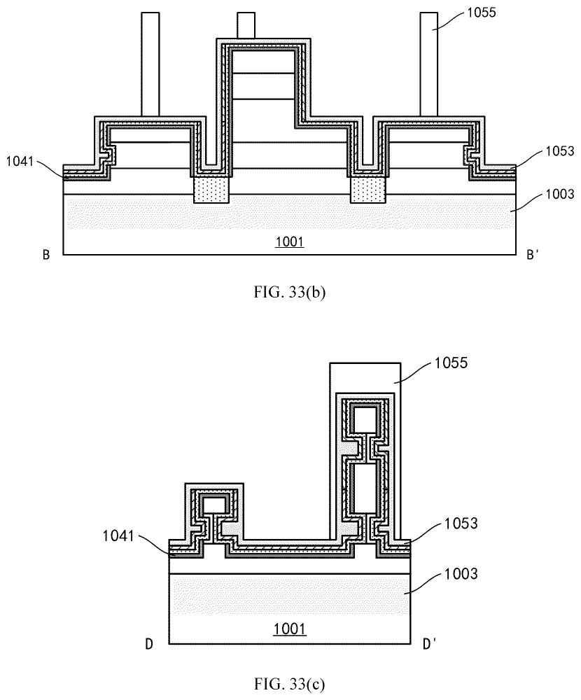

For example, as shown in FIG. 33(a), FIG. 33(b), and FIG. 33(c) (which are a top view, a cross-sectional view along line BB′, and a cross-sectional view along line DD′, respectively), a photoresist 1055 may be coated on the gate conductor layer 1053 and may be patterned through photolithography in such a pattern that covers the regions where the first to fourth connection portions CP1, CP2, CP3, and CP4 are to be formed as described above. Regarding the layout of the connection portions, it has been described in detail in combination with FIG. 2 and FIG. 3(a) to FIG. 3(c), which will not be repeated here. It should be noted that in the second sub-region and the third sub-region, the connection portions may be formed similar to those in the first sub-region and the fourth sub-region (in the case of a memory cell array, the pass-gate transistors of other SRAM cells may be formed in the second sub-region and the third sub-region).

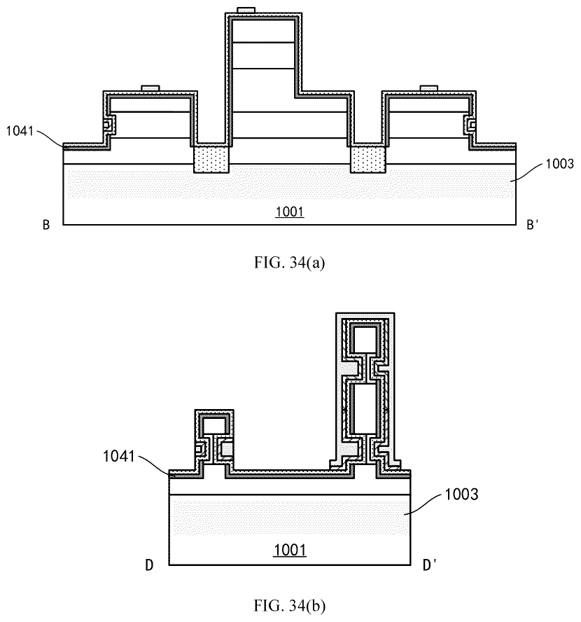

As shown in FIG. 34(a) and FIG. 34(b) (which are a cross-sectional view along line BB′, and a cross-sectional view along line DD′, respectively), the gate conductor layer 1053 and the work function adjustment layers 1045 and 1049 may be selectively etched using a photoresist 1055 as an etching mask. After that, the photoresist 1055 may be removed. Therefore, the gate conductor layer 1053 and the work function adjustment layers 1045 and 1049 remain not only in the gate space, but also in the region covered by the photoresist 1055 (forming the aforementioned connection portion). In the cross-sectional view of FIG. 34(b), the configuration of the connection portion may be clearly seen. As shown in the right part of FIG. 34(b), the connection portion may electrically connect the gate conductor layers on opposite sides of the channel layer to each other, and may also electrically connect the gate conductor layers of the stacked upper and lower transistors to each other.

Next, interconnection structures such as various via holes and wiring may be manufactured.

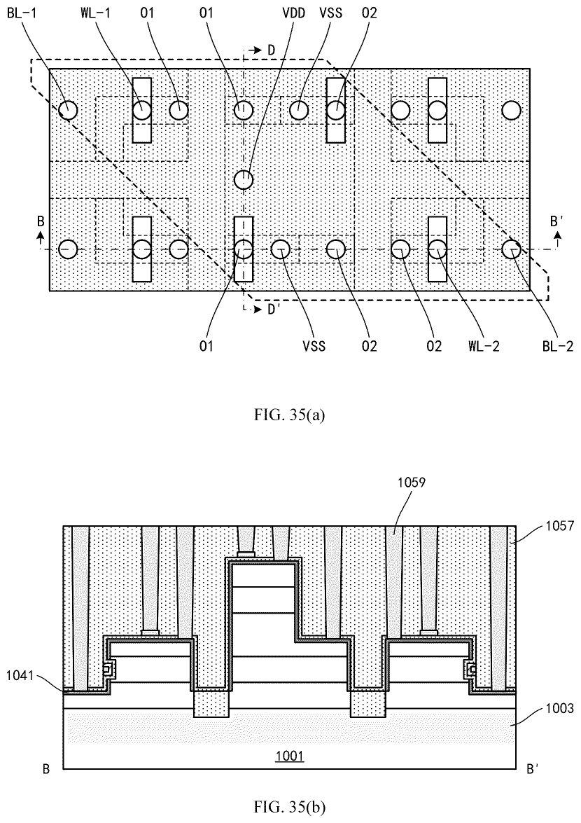

For example, as shown in FIG. 35(a), FIG. 35(b), and FIG. 35(c) (which are a top view, a cross-sectional view along line BB′, and a cross-sectional view along line DD′, respectively), an interlayer dielectric layer 1057 may be formed. In the interlayer dielectric layer 1057, contact holes may be etched and filled with a conductive material to form various contact portions 1059. Regarding the formation of the interlayer dielectric layer and the contact portions, there are various techniques in the art, which will not be repeated here. In the top view of FIG. 35(a), each contact portion is denoted with the same reference numeral as in FIG. 2. Regarding electrical connections of these contact portions, reference may be made to the description above in conjunction with FIG. 2 and FIG. 3(a) to FIG. (c).

In addition, in the top view of FIG. 35(a), the region of the SRAM cell is schematically shown by a dashed box. When arranging SRAM cells in an array form in a memory device, such SRAM cells may be repeatedly arranged in the first direction and the second direction, as shown in the top view of FIG. 36. In FIG. 36, only the repetitions in the first direction are shown, there may also be repetitions in the second direction, and there may be isolation trenches (e.g., extending in the first direction) between the repeating cells in the second direction.

According to embodiments of the present disclosure, the SRAM cell may be applied to various electronic devices. For example, a memory may be formed based on such SRAM cells, and an electronic device may be constructed therefrom. Therefore, the present disclosure further provides a memory including the above-mentioned SRAM cells and an electronic device including such memory. The electronic device may further include components such as a processor cooperating with the memory. The electronic device may include, for example, a smart phone, a personal computer (PC), a tablet computer, a wearable smart device, a portable power supply, and so on.

In the above description, the technical details such as patterning and etching of each layer have not been described in detail. However, those skilled in the art should understand that various technical means may be used to form layers, regions, etc. of required shapes. In addition, in order to form the same structure, those skilled in the art may further design a method that is not completely the same as the method described above. In addition, although various embodiments are described above separately, this does not mean that the measures in the various embodiments may not be advantageously used in combination.

The embodiments of the present disclosure are described above. However, these embodiments are only for the purpose of illustration, and are not intended to limit the scope of the present disclosure. The scope of the present disclosure is defined by the appended claims and the equivalents thereof. Without departing from the scope of the present disclosure, various substitutions and modifications may be made by those skilled in the art, and these substitutions and modifications should all fall within the scope of the present disclosure.

What is claimed is:

1. A static random access memory (SRAM) cell, comprising:
a substrate;
a first pull-up transistor, a second pull-up transistor, a first pass-gate transistor, and a second pass-gate transistor at substantially a same height relative to the substrate; and
a first pull-down transistor and a second pull-down transistor at substantially a same height relative to the substrate,
wherein the first pull-down transistor is stacked on the first pull-up transistor, and the second pull-down transistor is stacked on the second pull-up transistor, and
wherein an active region of each of the first pull-up transistor, the second pull-up transistor, the first pull-down transistor, the second pull-down transistor, the first pass-gate transistor, and the second pass-gate transistor comprises a first source/drain layer, a channel layer and a second source/drain layer sequentially disposed in a vertical direction, and the channel layer is in a form of a vertical nanosheet.

2. The SRAM cell according to claim 1, wherein in a top view, the active regions of the stacked first pull-up transistor and first pull-down transistor are in a first linear shape extending in a first direction, the active regions of the stacked second pull-up transistor and second pull-down transistor are in a second linear shape extending in the first direction, and the first linear shape and the second linear shape are spaced apart from each other and aligned with each other in a second direction intersecting with the first direction.

3. The SRAM cell according to claim 2, wherein
the active region of the first pass-gate transistor has a first portion, and the first portion in the top view is in a third linear shape spaced apart from and aligned with the first linear shape in the first direction;
the active region of the second pass-gate transistor has a first portion, and the first portion in the top view is in a fourth linear shape spaced apart from and aligned with the second linear shape in the first direction.

4. The SRAM cell according to claim 3, wherein
the active region of the first pass-gate transistor further has a second portion extending from the first portion of the active region of the first pass-gate transistor in the second direction, so that the active region of the first pass-gate transistor is in a broken linear shape in the top view;
the active region of the second pass-gate transistor further has a second portion extending from the first portion of the active region of the second pass-gate transistor in the second direction, so that the active region of the second pass-gate transistor is in a broken linear shape in the top view.

5. The SRAM cell according to claim 3, wherein the first pass-gate transistor is on a first side in the first direction relative to the first pull-up transistor and the first pull-down transistor, and the second pass-gate transistor is on a second side opposite to the first side in the first direction relative to the second pull-up transistor and the second pull-down transistor.

6. The SRAM cell according to claim 2, wherein the first source/drain layer, the channel layer and the second source/drain layer of each of the first pull-up transistor, the first pull-down transistor, the second pull-up transistor and the second pull-down transistor extend in the first direction, and the first source/drain layer and the second source/drain layer protrude towards two sides relative to the channel layer in the second direction.

7. The SRAM cell according to claim 6, further comprising:
a first pull-up gate stack between the first source/drain layer of the first pull-up transistor and the second source/drain layer of the first pull-up transistor, sandwiching the channel layer on opposite sides in the second direction;
a second pull-up gate stack between the first source/drain layer of the second pull-up transistor and the second source/drain layer of the second pull-up transistor, sandwiching the channel layer on opposite sides in the second direction;
a first pull-down gate stack between the first source/drain layer of the first pull-down transistor and the second source/drain layer of the first pull-down transistor, sandwiching the channel layer on opposite sides in the second direction; and
a second pull-down gate stack between the first source/drain layer of the second pull-down transistor and the second source/drain layer of the second pull-down transistor, sandwiching the channel layer on opposite sides in the second direction,
wherein the SRAM cell further comprises:
a first connection portion extending from one side to the other side in the second direction across the stacked first pull-up transistor and first pull-down transistor, and electrically connecting the gate stacks of each of the first pull-up transistor and the first pull-down transistor on two sides of the channel layer to each other; and
a second connection portion extending from one side to the other side in the second direction across the stacked second pull-up transistor and second pull-down transistor, and electrically connecting the gate stacks of each of the second pull-up transistor and the second pull-down transistor on two sides of the channel layer to each other.

8. The SRAM cell according to claim 7, wherein
the second source/drain layer of the first pull-up transistor and/or the first source/drain layer of the first pull-down transistor, the second source/drain layer of the first pass-gate transistor, and the second connection portion are electrically interconnected with each other;
the second source/drain layer of the second pull-up transistor and/or the first source/drain layer of the second pull-down transistor, the second source/drain layer of the second pass-gate transistor, and the first connection portion are electrically interconnected with each other.

9. The SRAM cell according to claim 7, wherein each of the first connection portion and the second connection portion is integrated with a gate conductor in a corresponding gate stack.

10. The SRAM cell according to claim 6, wherein the channel layer of each of the first pull-up transistor and the second pull-up transistor has a first width in the first direction, and the first pull-down transistor and the second pull-down transistor have a second width less than the first width in the first direction.

11. The SRAM cell according to claim 4,
wherein in the first portion of the active region of each of the first pass-gate transistor and the second pass-gate transistor, the first source/drain layer, the channel layer and the second source/drain layer extend in the first direction, and the first source/drain layer and the second source/drain layer protrude towards two sides relative to the channel layer in the second direction;
wherein in the second portion of the active region of each of the first pass-gate transistor and the second pass-gate transistor, the first source/drain layer, the channel layer and the second source/drain layer extend in the second direction, and the first source/drain layer and the second source/drain layer protrude towards two sides relative to the channel layer in the first direction,
wherein the SRAM cell further comprises:
a first pass-gate stack between the first source/drain layer of the first pass-gate transistor and the second source/drain layer of the first pass-gate transistor, sandwiching the channel layer from opposite sides of the channel layer;
a second pass-gate stack between the first source/drain layer of the second pass-gate transistor and the second source/drain layer of the second pass-gate transistor, sandwiching the channel layer from opposite sides of the channel layer;
a third connection portion extending from one side to an opposite side across the first pass-gate transistor; and
a fourth connection portion extending from one side to an opposite side across the second pass-gate transistor,
wherein the third connection portion and the fourth connection portion are electrically connected to a word line.

12. The SRAM cell according to claim 3,
wherein the second source/drain layer of the first pull-up transistor and/or the first source/drain layer of the first pull-down transistor have a first protruding portion protruding in the first direction relative to the active region above on a side close to the first pass-gate transistor, and the first protruding portion and the second source/drain layer of the first pass-gate transistor are electrically interconnected with each other;
wherein the second source/drain layer of the second pull-up transistor and/or the first source/drain layer of the second pull-down transistor have a third protruding portion protruding in the first direction relative to the active region above on a side close to the second pass-gate transistor, and the third protruding portion and the second source/drain layer of the second pass-gate transistor are electrically interconnected with each other; and
wherein a top surface of the first protruding portion is substantially coplanar with a top surface of the second source/drain layer of the first pass-gate transistor, and a top surface of the second protruding portion is substantially coplanar with a top surface of the second source/drain layer of the second pass-gate transistor.

13. The SRAM cell according to claim 3, wherein
the first source/drain layer of the first pass-gate transistor has a second protruding portion protruding relative to the active region above;
the first source/drain layer of the second pass-gate transistor has a fourth protruding portion protruding relative to the active region above.

14. The SRAM cell according to claim 1, further comprising:
a base extending in the second direction, wherein the first source/drain layer of each of the first pull-up transistor and the second pull-up transistor is provided on the base and integrated with the base,
wherein the second source/drain layer of the first pull-up transistor is in direct contact with or integrated with the first source/drain layer of the first pull-down transistor; and the second source/drain layer of the second pull-up transistor is in direct contact with or integrated with the first source/drain layer of the second pull-down transistor; and
wherein a gate stack of each of the first pull-up transistor, the second pull-up transistor, the first pull-down transistor, the second pull-down transistor, the first pass-gate transistor and the second pass-gate transistor is self-aligned with a corresponding channel layer.

15. The SRAM cell according to claim 2, further comprising:
an isolation trench defining the active region in the substrate, wherein the active region comprises a first region, a second region and a third region, the second region and the third region are respectively provided on opposite sides of the first region in the first direction and isolated from the first region, the second region comprises a first sub-region and a second sub-region opposite to the first sub-region in the second direction, the first sub-region is electrically isolated from the second sub-region, the third region comprises a third sub-region and a fourth sub-region opposite to the third sub-region in the second direction, the third sub-region is electrically isolated from the fourth sub-region, and the first sub-region and the fourth sub-region are diagonally disposed,
wherein the first pull-up transistor, the first pull-down transistor, the second pull-up transistor and the second pull-down transistor are provided in the first region, the first pass-gate transistor is provided in the first sub-region, and the second pass-gate transistor is provided in the fourth sub-region.

16. A memory comprising an array of SRAM cells of claim 1.

17. An electronic device comprising a memory of claim 16 and a processor operatively coupled to the memory.

18. The electronic device according to claim 17, comprising a smart phone, a computer, a tablet computer, a wearable smart device, an artificial intelligence device, and a mobile power supply.

19. A method of manufacturing a static random access memory (SRAM) cell, comprising:
sequentially providing a stack of a first group and a second group on a substrate, wherein the first group comprises a first source/drain layer, a first channel defining layer and a second source/drain layer, and the second group comprises a first source/drain layer, a second channel defining layer and a second source/drain layer;
forming an isolation trench in the stack, such that the stack comprises a first region, a second region and a third region, wherein the second region and the third region are respectively provided on opposite sides of the first region in a first direction and isolated from the first region, the second region comprises a first sub-region and a second sub-region opposite to the first sub-region in a second direction, wherein the first sub-region is electrically isolated from the second sub-region, the third region comprises a third sub-region and a fourth sub-region opposite to the third sub-region in the second direction, wherein the third sub-region is electrically isolated from the fourth sub-region, wherein the first sub-region and the fourth sub-region are diagonally disposed;
forming a hard mask layer on the stack, wherein the hard mask layer has a rectangular ring pattern, the rectangular ring pattern has edges extending in the first direction and the second direction respectively, and four corners of the rectangular ring pattern are in the first sub-region, the second sub-region, the third sub-region, and the fourth sub-region respectively;
patterning an outer side of the stack using the hard mask layer;
selectively etching the channel defining layer, such that the channel defining layer is relatively recessed in a lateral direction;
forming a channel layer on a vertical sidewall of the channel defining layer;
patterning an inner side of the stack using the hard mask layer;
removing the first channel defining layer and the second channel defining layer from the inner side of the stack;
lowering a height of the stack in the first sub-region to the fourth sub-region and a partial region of the first region to a level between a bottom surface of the second source/drain layer of the first group and a top surface of the first source/drain layer of the second group, wherein in the partial region of the first region corresponding to a partial length of each of two opposite edges of the rectangular ring pattern extending in the first direction, the stack retains the second group comprising the first source/drain layer, the second channel defining layer and the second source/drain layer; and
forming a gate stack in a space left between the first source/drain layer and the second source/drain layer due to a removal of corresponding channel defining layers in the first channel defining layer and the second channel defining layer.

20. The method according to claim 19, wherein the rectangular ring pattern of the hard mask layer is defined by a spacer.
